(19) United States
(12) Patent Application Publication
(10) Pub. No.: US 2024/0222565 A1
(43) Pub. Date: Jul. 4, 2024

(54) LED DEVICE AND INK COMPOSITION COMPRISING THE SAME

(71) Applicant: Kookmin University Industry Academy Cooperation Foundation, Seoul (KR)

(72) Inventor: Young Rag DO, Seoul (KR)

(21) Appl. No.: 18/397,445

(22) Filed: Dec. 27, 2023

(30) Foreign Application Priority Data
Dec. 28, 2022 (KR) 10-2022-0187631

(51) Int. Cl. H01L 33/44; H01L 25/075

(52) U.S. Cl. CPC H01L 33/44; H01L 25/0753

(57) ABSTRACT

Disclosed herein are a light-emitting diode (LED) device, and an ink composition including the same, which can reduce an exposed area of a photoactive layer exposed at a surface to prevent a decrease in efficiency due to a surface defect, and repair the surface defect and minimize degradation in light emission efficiency due to the surface defect even when the surface defect occurs to maintain high efficiency in light extraction efficiency and, simultaneously, minimize a side surface contact through a mounting method using dielectrophoresis when LED devices are self-aligned on a mounting electrode to improve a drivable (or light emittable) mounting efficiency.

### CROSS-REFERENCE TO RELATED APPLICATION

This application claims priority to and the benefit of Korean Patent Application No. 10-2022-0187631, filed on Dec. 28, 2022, the disclosure of which is incorporated herein by reference in its entirety.

### BACKGROUND

### 1. Field of the Invention

The present invention relates to a light-emitting diode (LED) device, and more specifically, to an LED device and an ink composition including the same.

### 2. Discussion of Related Art

Micro light-emitting diodes (LEDs) and nano LEDs are capable of implementing excellent colors and high efficiencies and are eco-friendly materials, and thus they are used as core materials for a display. In line with such a market situation, research has recently been conducted to develop LEDs through new nano LED structures or new manufacturing processes.

It is known that the existing individual LED devices can be manufactured using a bottom-up method and a top-down method, but some prefer manufacturing individual LED devices using the bottom-up method based on a chemical growth method. However, it is not easy to manufacture hundreds of millions of micro individual LED devices as small as nanoscale using the bottom-up method, and even though micro individual LED devices are manufactured, it is difficult to manufacture each LED device to have a uniform size and a uniform characteristic.

On the other hand, the top-down method has an advantage in that a wafer is etched to the desired size and number from a large-area wafer and then the remaining LED structures etched from the wafer are separated from the wafer so that tens or hundreds of millions of individual LED devices with uniform characteristics can be manufactured.

However, in the top-down method, a process of etching the wafer in a vertical direction is inevitably performed to manufacture the LED structure, and a side surface of the LED structure is damaged due to treatment with etchant or plasma applied in the etching process so that this causes a significant decrease in light emission efficiency of the device itself.

Meanwhile, as a technology of etching a wafer to achieve an LED structure with a desired size and a desired shape and a technology of separating the etched LED structure from the wafer are developed, it becomes possible that a shape of an LED device that is previously difficult to manufacture using commercially available wafers, for example, has a rod shape with an aspect ratio of more than 1, and the LED structure is etched by making an etching depth much shallower than a length and then separated from the wafer.

However, as the size of the LED device with the above shape becomes smaller, it is still impossible to mount the LED device individually on an electrode using a pick-and-place method, which is one of the conventional mounting techniques. In order to solve these difficulties, Korean Registered Patent No. 10-1436123 (Patent Document 1) discloses a mounting method using dielectrophoresis, which nanorod-type LED devices with an aspect ratio of more than 1 are put onto electrodes within a subpixel and then are self-aligned on two electrodes by forming an electric field between the two electrodes.

In this case, since a major axis of the nanorod-type LED device of Patent Document 1 coincides with a stacked direction of layers forming the device, both ends of the LED device in a major axis direction are inevitably positioned on conductive semiconductor layers of different polarities using dielectrophoresis. In addition, when the major axis direction is defined as upper/lower portions, side surfaces of the device has the same shape/stacked structure regardless of whether the device has a cylindrical shape or a rectangular parallelepiped shape. Thus, when the mounting method using dielectrophoresis is applied to the nanorod-type LED device used in Patent Document 1, the LED device becomes a light emission state simply when the both ends of the LED device in the major axis direction are mounted to be positioned between the two electrodes or mounted on upper surfaces of the two electrodes, and which of the side surfaces of the LED device should be in contact with the electrodes does not affect whether the LED device emits light.

However, unlike the LED device disclosed in Patent Document 1, when the mounting method using dielectrophoresis of Patent Document 1 is applied to an LED device in which a stacked direction of layers forming the LED device is different from a direction of a major axis having the longest length, the LED device is self-aligned to allow both ends thereof in the major axis direction to be in contact with electrode surfaces of two separated electrodes. However, when surfaces perpendicular to the major axis direction of the LED device are defined as upper/lower surfaces, side surfaces of the LED device are formed of three different types (one n-type conductive semiconductor surface, one p-type conductive semiconductor surface, and two n-type conductive semiconductor/photoactive layer/p-type conductive semiconductor surfaces) so that a probability of the LED device being mounted to emit light is simply ½ when calculated arithmetically.

Therefore, when the mounting method using dielectrophoresis is applied to an LED device in which a stacked direction of layers forming the LED device is different from a direction of a major axis having the longest length, there is a problem in that, since the number of LED devices mounted to emit light is only ⅓ compared to that of LED devices put into, a brightness characteristic of an implemented light source is not good compared to a manufacturing cost. In addition, the LED devices mounted not to emit light causes a problem of causing an electrical short circuit or generating a leakage current so that there is a limitation in applying the LED devices with such a stacked structure and shape, which are implemented through the mounting method using dielectrophoresis, as LED electrode assemblies or light sources of displays.

### SUMMARY OF THE INVENTION

The present invention is directed to providing a light-emitting diode (LED) device and an ink composition including the same, which can reduce an exposed area of a photoactive layer exposed at a surface to prevent a decrease in efficiency due to a surface defect, and repair the surface defect and minimize degradation in light emission efficiency due to the surface defect even when the surface defect occurs to maintain high efficiency in light extraction efficiency and, simultaneously, minimize a side surface contact through a mounting method using dielectrophoresis when the LED devices is self-aligned on a mounting electrode to improve a drivable (or light emittable) mounting efficiency.

The present invention is also directed to providing an LED electrode assembly which is implemented using a mounting method using dielectrophoresis to increase drivable mounting efficiency while allowing a specific surface to selectively come into contact with a mounting electrode, and an LED device, an ink composition containing the same, and an LED electrode assembly implemented using the same, which expand a selection width of power used in light sources such as displays to DC power to achieve high brightness and high light emission efficiency.

The present invention is also directed to providing an LED device and an ink composition containing the same, which can prevent an electrical short circuit or current leakage caused by layers constituting the LED device chemically attacked by various types of etchants applied in a manufacturing process of the LED device and/or a photoactive layer of the LED device exposed to an etchant applied in various deposition and etching processes performed after self-aligning the LED device on the electrode.

According to an aspect of the present invention, there is provided a light-emitting diode (LED) device including a first surface and a second surface of which a first axis becomes a major axis based on the first axis and a second axis mutually perpendicular to each other and which are opposite to each other in a second axis direction in which a plurality of layers including a photoactive layer are stacked; remaining side surfaces, and a cover layer surrounding the remaining side surfaces, wherein the cover layer includes a first cover layer configured to passivate the side surfaces in order to protect the side surfaces and remove a defect on the side surfaces, and a second cover layer disposed on the first cover layer and configured to generate a rotational torque around an imaginary rotation axis passing through a center of the LED device in a first axis direction when an electric field and mobile medium are present.

The plurality of layers may include an n-type conductive semiconductor layer, a photoactive layer, and a p-type conductive semiconductor layer.

In the LED device, a length in the first axis direction may range from 1 μm to 10 μm, and a thickness in the second axis direction may range from 0.1 μm to 3 μm.

The first cover layer may have an electrical conductivity of 1×10⁻⁶ S/m.

The LED device may be an LED device for self-alignment using a dielectrophoretic force, and the self-alignment may be a method in which the LED devices dispersed in the mobile medium move toward the mounting electrode generating an electric field, and one sides of the LED devices are aligned to come into contact with an upper surface of the mounting electrode.

The second cover layer may be a layer in which a real part of a K(ω) value according to the following Equation 1 ranges from more than 0 to 0.72 or less within at least some frequency ranges of a frequency range of 1 kHz and 10 GHZ, and more preferably the real part of the K(ω) value according to Equation 1 ranges from more than 0 to 0.62 or less.

$$\\ \begin{matrix}K ( ω ) = \frac{{ε}_{p}^{{}_{} *} - {ε}_{m}^{{}_{} *}}{{ε}_{p}^{{}_{} *} + 2 {ε}_{m}^{{}_{} *}} & [ Equation 1 ]\end{matrix}$$

In Equation 1, K(ω) may be an equation between εₚ* indicating a complex permittivity of a spherical core-shell particle made of GaN as a core portion and the second cover layer as a shell portion at an angular frequency ω and εₘ* indicating a complex permittivity of the mobile medium, and εₚ* may be calculated according to the following Equation 2.

$$\\ \begin{matrix}{ε}_{p}^{{}_{} *} = {ε}_{2}^{{}_{} *} \frac{{( \frac{{R}_{2}}{{R}_{1}} )}^{3} + 2 ( \frac{{ε}_{1}^{{}_{} *} - {ε}_{2}^{{}_{} *}}{{ε}_{1}^{{}_{} *} + 2 {ε}_{2}^{{}_{} *}} )}{{( \frac{{R}_{2}}{{R}_{1}} )}^{3} - ( \frac{{ε}_{1}^{{}_{} *} - {ε}_{2}^{{}_{} *}}{{ε}_{1}^{{}_{} *} + 2 {ε}_{2}^{{}_{} *}} )} & [ Equation 2 ]\end{matrix}$$

In Equation 2, R₁ may denote a radius of a core portion, R₂ may denote a radius of the core-shell particle, and ε₁* and ε₂* may be complex permittivities of the core portion and a shell portion, respectively.

A thickness of the first cover layer may range from 1 nm to 60 nm, and a thickness of the second cover layer may range from 1 nm to 60 nm.

The cover layer may further include a third cover layer serving as a resistance layer against dry and wet etching between the first cover layer and the second cover layer.

The second cover layer and third cover layer may have an etch ratio B/A of 2.0 more, which is a ratio between an etch rate A (nm/min) of the second cover layer and an etch rate B (nm/min) of the third cover layer under the same etching conditions.

A thickness of the third cover layer may range from 1 nm to 30 nm.

A top layer having the second surface may have a greater electrical conductivity coefficient than a bottom layer having the first surface.

The electrical conductivity coefficient of the top layer may be 10 times or more that of the bottom layer.

According to another aspect of the present invention, there is provided an ink composition including a plurality of LED devices and a mobile medium according to the present invention.

According to still another aspect of the present invention, there is provided an LED electrode assembly in which a first surface and a second surface of each of a plurality of LED devices according to the present invention are electrically connected to two electrodes spaced apart from each other in the second axis direction of the LED device.

Terms used herein will be defined below.

In the description of the embodiment according to the present invention, when each layer, a region, a pattern or a structure is described as being formed “on,” “above,” “up,” “under,” or “down” a substrate, each layer, a region, or a pattern, “on,” “above,” “up,” “under,” and “down” include both the meanings of “directly” and “indirectly.”

In addition, as a term used in the present invention, “drivable mounting ratio” means a ratio of the number of LED devices mounted in a drivable form to all LED devices mounted on a lower electrode line. In addition, “selective mounting ratio” means a ratio of the number of LED devices, in which any one of a first surface B and a second surface T of the LED device comes into contact with an upper surface of the lower electrode line, to all the LED devices mounted on the lower electrode line.

Meanwhile, it is noted that the present invention was invented with the support of the following national research and development projects.
[National Research and Development Project 1]
[Project Unique Number] 1711130702
[Project Number] 2021R1A2C2009521
[Name of Ministry] Ministry of Science and ICT
[Name of Project Management (Professional) Organization] National Research Foundation of Korea
[Research Task Name] Mid-career researcher support project
[Research Project Name] Development of Dot-LED material and display source/application technology
[Contribution Ratio] 1/2
[Name of Institution Performing Project] Kookmin University Industry-Academic Cooperation Foundation
[Research Period] Mar. 1, 2023 to Feb. 29, 2024
[National Research and Development Project 2]
[Project Unique Number] 1415174040
[Project Number] 20016290
[Name of Ministry] Ministry of Trade, Industry and Energy
[Name of Project Management (Professional) Organization] Korea Institute of Industrial Technology Evaluation and Planning
[Research Task Name] Electronic component industry technology development—ultra-large micro LED modular display
[Research Project Name] Development of sub-micron level blue light source technology for modular displays
[Contribution Ratio] 1/2
[Name of Institution Performing Project] Kookmin University Industry-Academic Cooperation Foundation
[Research Period] Jan. 1, 2023 to Dec. 31, 2023

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIGS. 1 and 2 are a perspective view and a cross-sectional view along line X-X′ of a light-emitting diode (LED) according to one embodiment of the present invention, respectively;

FIGS. 3 to 5 are transverse cross-sectional views illustrating LED devices in a direction perpendicular to a longitudinal direction according to embodiments of the present invention;

FIGS. 6A to 6C are plan views of LED devices in a plane d1-d2 according to the embodiments of the present invention;

FIG. 7 is a schematic diagram illustrating mounting of the LED device according to one embodiment of the present invention, in which rod-type devices, each having a major axis in the longitudinal direction perpendicular to a thickness direction, are stacked in the form of several layers in the thickness direction and are mounted on mounting electrodes;

FIGS. 8 and 9 are graphs showing a real part of a value according to Equation 1 for each frequency of an electric field formed when a single particle formed of each shown material is placed in media of acetone and isopropyl alcohol;

FIGS. 10A to 10D graphs showing a real part of a value according to Equation 1 for each frequency of an electric field formed when a spherical core-shell particle, in which a second cover layer formed of each shown material with a thickness of 30 nm is formed on a surface of a GaN core with a radius of 400 nm is placed in mobile media with dielectric constants of 10, 15, 20.7, and 28;

FIGS. 11 and 12 are schematic diagrams illustrating a movement of an LED device placed in a medium above mounting electrodes where electric fields are formed when the LED device is mounted on the mounting electrodes through a dielectrophoretic force, wherein FIG. 11 is a schematic diagram illustrating the movement of the LED device driven by surfaces of two adjacent mounting electrode, and FIG. 12 is a schematic diagram illustrating a rotational torque generated in the LED device based on a x-axis that is the major axis of the LED device;

FIG. 13 shows scanning electron microscope (SEM) photographs of various mounting states after the LED device according to one embodiment of the present invention is mounted on the mounting electrodes through dielectrophoresis;

FIG. 14 is a cross-sectional schematic diagram illustrating a state in which the LED device according to one embodiment of the present invention is capable of being mounted after self-alignment on electrodes;

FIG. 15 is a cross-sectional schematic diagram illustrating an LED electrode assembly according to one embodiment of the present invention; and

FIG. 16 is a schematic diagram illustrating a process of manufacturing an LED device according to one embodiment of the present invention.

### DETAILED DESCRIPTION OF EXEMPLARY EMBODIMENTS

Hereinafter exemplary embodiments of the present invention will be described in detail which is suitable for easy implementation by those skilled in the art with reference to the accompanying drawings. The present invention may be implemented in various different forms, and thus it is not limited to embodiments to be described herein.

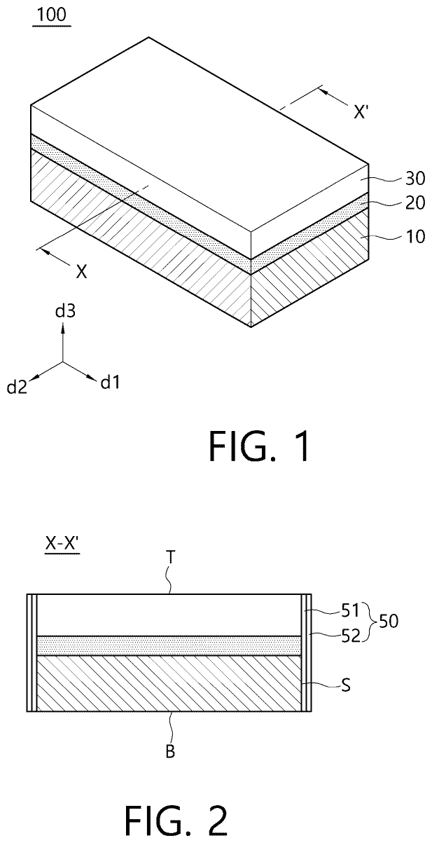

To describe with reference to FIGS. 1 to 4, light-emitting diode (LED) devices 100, 100′, 101, and 102 according to one embodiment of the present invention each include a first surface B and a second surface T, which are opposite in a direction of a second axis d3 in which a plurality of layers including a photoactive layer 20 are stacked based on a first axis d1 and a second axis d3 that are perpendicular to each other, and the remaining side surfaces S, are devices in each of which the first axis d1 becomes a major axis of the longest length of the LED device, and each include cover layers 50 and 50′ surrounding the side surface S.

The cover layers 50 and 50′ include a first cover layer 51, which serves as passivation of the side surface S of the LED device to protect the side surface S and remove defects on the side surface S, and a second cover layer 52, which generates a rotational torque about an imaginary rotation axis that passing through the center of the LED device in a first axis direction in the presence of an electric field and a mobile medium.

When two opposite surfaces in a direction of the first axis d1 are referred to as an upper surface and a lower surface, the first cover layer 51 is a layer which surrounds the side surfaces S to be in contact therewith. When a wafer is etched in the thickness direction, surface defects are likely to occur in layers, that is, conductive semiconductor layers 10 and 30 and a photoactive layer 20, constituting the wafer exposed to an etched surface, and the surface defects may significantly degrade light emission efficiency. Thus, the first cover layer 51 removes and repairs defects occurring on surfaces of etched conductive semiconductor layers 10 and 30 and a photoactive layer 20 and serves to protect the side surface S so as to prevent surface damage to the side surface S, which may occur in subsequent processes using individually manufactured LED devices 100, 100′, 101, and 102.

A known material with an insulating property may be used without limitation as the first cover layer 51 as long as it can serve as passivation for the surfaces of the conductive semiconductor layers 10 and 30 and the photoactive layer 20, and thus the first cover layer 51 may have an electrical conductivity of 1×10⁻⁶ S/m or less.

As a non-limiting example, the first cover layer 51 may be formed as a single layer made of one or more inorganic materials selected from the group consisting of silicon nitride (SiNₓ), silicon dioxide (SiO₂), aluminum oxide (Al₂O₃), hafnium oxide (HfO₂), zirconium oxide (ZrO₂), yttrium oxide (Y₂O₃), lanthanum oxide (La₂O₃), scandium oxide (Sc₂O₃), titanium dioxide (TiO₂), aluminum nitride (AlN), gallium nitride (GaN), aluminum gallium nitride (AlGaN), and indium gallium nitride (InGaN), one or more polymers selected from the group consisting of polyimide (PI), polymethylmethacrylate (PMMA), polyethylene (PE), polystyrene (PS), polyurethane (PU), polyvinylpyrrolidone (PVP), and a polymer, or formed as a composite layer made of two or more of these inorganic materials and polymers.

In addition, the first cover layer 51 may have a thickness ranging from 1 nm to 60 nm, and when the thickness is less than 1 nm, an effect of repairing the surface defects through passivation can be insignificant. Additionally, when the thickness is more than 60 nm, manufacturing costs can increase.

In addition, the cover layers 50 and 50′ each includes a second cover layer 52 disposed on the first cover layer 51 as the outermost layer of each of the cover layers 50 and 50′. The second cover layer 52 is responsible for generating a rotational torque based on an imaginary rotation axis passing through the center of each of the LED devices 100, 100′, 101, and 102 in the first axis direction in the presence of an electric field and a mobile medium.

One of the mounting methods of driving small-sized LED device which is difficult to be mounted using a pick-and-place mounting method is dielectrophoresis using an electric field. Through the dielectrophoresis, the LED devices dispersed in the mobile medium move and are self-aligned on electrodes on which the LED devices are mounted. During the dielectrophoresis using an electric field, when a separation distance between two different electrodes forming electric fields, for example, two different electrodes, is smaller than a length of the major axis of the LED device, both ends of the LED device in the major axis direction move and align to come into contact with upper surfaces of the two different electrodes. However, the LED device completing the movement and alignment is not always in a drivable mounted state. That is, when a direction in which the layers constituting the LED device are stacked is the same as the major axis direction, when the movement and alignment are completed through the dielectrophoresis using an electric field, the LED device becomes a drivable state immediately. However, when the direction in which the layers constituting the LED device are stacked is perpendicular to the major axis direction, the LED device becomes a drivable mounted state or a non-drivable mounted state.

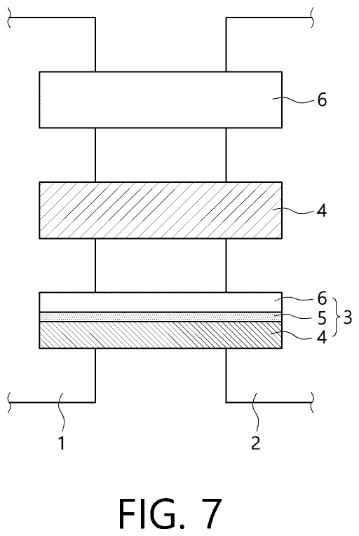

In describing with reference to FIG. 7, in an electric field formed by applying different power to two lower electrodes 1 and 2, LED devices 3 dispersed in a mobile medium move toward the lower electrodes 1 and 2 by a dielectrophoretic force and both ends of the major axis direction of the LED device 3 self-align to come into contact with upper surfaces of the two adjacent lower electrodes 1 and 2. In this case, when a surface of the LED device coming into contact with the upper surfaces of lower electrodes 1 and 2 is defined as a mounting surface, surfaces of the LED device to be mounting surfaces are four surfaces of the LED device, excluding two surfaces opposite to the major axis of the LED device. In the LED device 3 of which the major axis direction is perpendicular to the stacked direction of layers 4, 5, and 6 constituting the LED device 3, the side surfaces are divided into three different types such as a first conductive semiconductor layer 4, a second conductive semiconductor layer 6, or a first conductive semiconductor layer 4/photoactive layer 5/second conductive semiconductor layer 6 (hereinafter referred to as a “first side surface”). When the first side surface, which occupies two of the four side surfaces, comes into contact with the upper surfaces of the lower electrodes 1 and 2, the LED device 3 cannot be driven due to the first cover layer 51 disposed on the first side surface. Even when the first cover layer 51 is not present, since all the three different device layers present on the first side surface comes into contact with the same type of the lower electrodes 1 and 2, there is a problem in that, when driving power is applied, a short circuit or current leakage is caused and thus light cannot be emitted.

Thus, in order to mount the LED devices 100, 100′, 101, and 102, in which the second axis d3 that is the direction in which the layers constituting the LED device are stacked is perpendicular to the first axis d1 that is the major axis direction, in a mountable state through dielectrophoresis using an electric field, the LED device should be mounted such that either the first surface B or the second surface T opposite to each other in the second axis direction comes into contact with the mounting electrode.

Therefore, further to self-align the LED devices 100, 100′, 101, and 102 on the mounting electrode using the electric field formed by the two mounting electrodes spaced apart from each other, while the present inventors are continuously researching dielectrophoresis methods in which the first surface B and the second surface T among the surfaces of the LED device come into contact with the mounting electrode, according to materials of the first surface B and the second surface T of the LED device and a material of the outermost cover layer covering the side surface which is the remaining surface other than the first surface B and the second surface T, the present inventors discover that the first surface B or the second surface T of the LED device is superior to the side surface S, and furthermore, that a specific one of the first surface B and the second surface T can be dielectrophoresed to come into contact with the upper surface of the mounting electrode so that the second cover layer 52 is derived.

Before describing the second cover layer 52 in detail, movement of particles in dielectrophoresis will be first described.

Specifically, the movement of particles in a medium during dielectrophoresis can be described through a dielectrophoresis mechanism, and dielectrophoresis is a phenomenon in which a directional force is applied to particles by a dipole induced in the particles when the particles are placed in a non-uniform electric field. In this case, a force strength may vary according to electrical properties and dielectric properties of the particle and the medium, and a frequency of an AC electric field, and a time average force F_{DEP} received by the particle during dielectrophoresis is expressed as the following Equation 3.

$$\\ \begin{matrix}{F}_{DEP} = 2 π {r}^{{}_{} 3} {ε}_{m} Re [ K ( ω ) ] ∇ {\vert E \vert}^{2} & [ Equation 3 ]\end{matrix}$$

In Equation 3, r, εₘ, and E denote a radius of the particle, a dielectric constant of the medium, and a root mean square magnitude of the applied AC electric field, respectively. In addition, Re[K(ω)] is a factor that determines a direction in which a nearly spherical particle moves and means a real part of a value according to the following Equation 1.

$$\\ \begin{matrix}K ( ω ) = \frac{{ε}_{p}^{{}_{} *} - {ε}_{m}^{{}_{} *}}{{ε}_{p}^{{}_{} *} + 2 {ε}_{m}^{{}_{} *}} & [ Equation 1 ]\end{matrix}$$

Here, εₚ* and εₘ* denote complex dielectric constants of the particle and the medium, respectively, and ε* is obtained by the following Equation 4.

$$\\ \begin{matrix}{ε}^{{}_{} *} = ε - j \frac{σ}{ω} & [ Equation 4 ]\end{matrix}$$

Here, σ denotes an electrical conductivity coefficient, ¿ denotes a dielectric constant, ω denotes an angular frequency (ω=2πf), and j denotes an imaginary part j=\sqrt{−1}.

In this case, the movement of particles during dielectrophoresis largely depends on a change in factors according to Equation 1. That is, a sign change according to the frequency of Re[K(ω)] is the most important factor in determining a direction of a phenomenon in which the particles move toward or away from a high electric field region. In this regard, when Re[K(ω)] has a positive value, the particles moving toward the high electric field region is positive dielectrophoresis (pDEP) and, when Re[K(ω)] has a negative value, the particles moving away from the high electric field region is negative dielectrophoresis (nDEP).

When the particles are LED devices, the LED devices receive a dielectrophoretic force in a state of being dispersed in a mobile medium which is the medium. An electrical conductivity coefficient and a dielectric constant of each type of material that can be included in the mobile medium and the LED device related to Equations 1, 3, and 4 are shown in the following Table 1.

TABLE 1

| | Mobile medium | | Materials that can be included in LED devices | | | | | |
|---|---|---|---|---|---|---|---|---|
| | acetone | IPA | GaN | ITO | SiO₂ | SiNₓ | Al₂O₃ | TiO₂ |
| Dielectric constant ε | 20.7 | 18.6 | 12.2 | 3.2 | 3.9 | 6.2 | 9.0 | 80 |
| Electrical conduc- | 20 × | 6 × | 1 × | 1 × | 1 × | 2 × | 1 × | 1 × |
| tivity σ (S/m) | 10⁻⁶ | 10⁻⁶ | 10⁴ | 10⁵ | 10⁻¹⁰ | 10⁻¹³ | 10⁻¹⁴ | 10⁻¹³ |

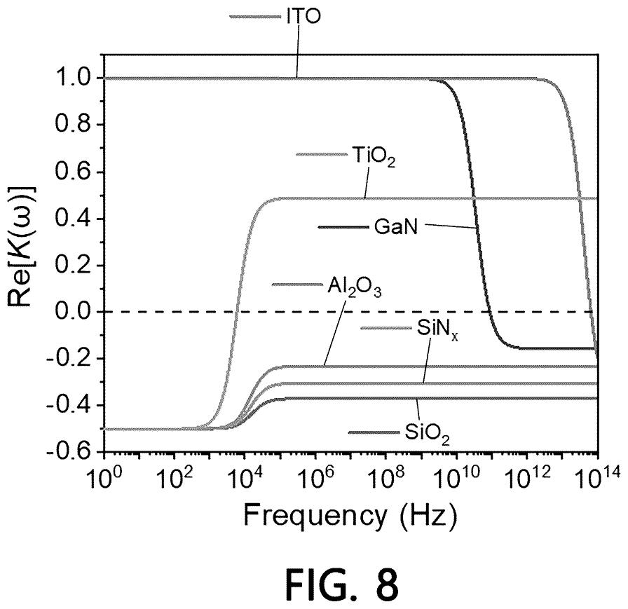

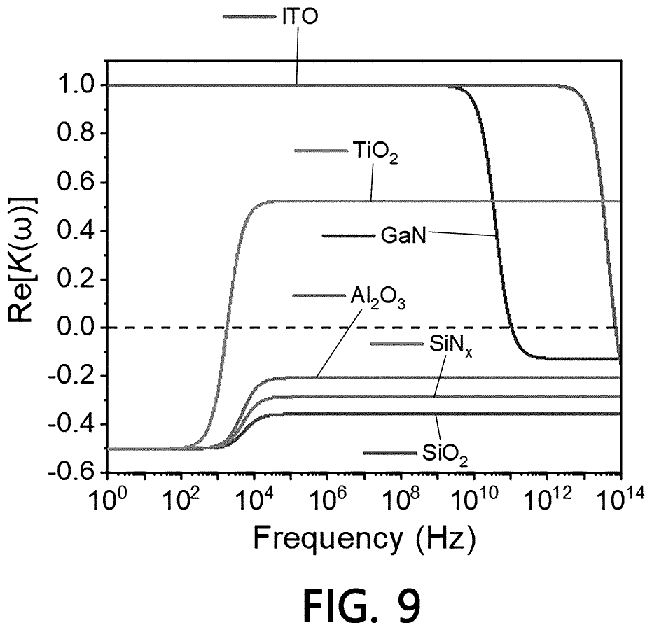

In addition, referring to FIGS. 8 and 9, as an example of the mobile medium, assuming that materials that can be included in the LED devices dispersed in acetone and isopropyl alcohol (IPA) is a single particle, a frequency dependence of Re[K(ω)] generally has a pDEP value in a wide frequency range in the case of ITO and GaN, whereas, in the case of TiO₂, the frequency dependence of Re[K(ω)] has a nDEP value at a low frequency and the pDEP value at a high frequency. In addition, particles of materials such as SiO₂, SiNₓ, and Al₂O have nDEP values regardless of a frequency. Therefore, GaN particles, ITO particles, or TiO₂ particles have a directionality in which they move toward or away from a strong electric field according to a frequency. In addition, particles of materials such as SiO₂, SiNₓ, and Al₂O always move in a direction away from a strong electric field regardless of the type of medium such as acetone or IPA and the frequency of the applied power.

Therefore, the dielectrophoretic force received by the LED device may control a desired surface to be selectively positioned on the mounting electrode by adjusting dielectric constants and electrical conductivities of materials constituting the LED device and the mobile medium, on which the LED device is placed, and a sign (positive/negative) and level of the [K(ω)] value which acts on each side of the LED device. However, since the LED device is not a single device made of one type of material, by using the experimental results of FIGS. 8 and 9, it is almost impossible to predict the movement of the LED device in which layers of various materials are stacked and the first cover layer 51 is formed on the side surface. Therefore, the inventor of the present invention assumes that a spherical particle is not a particle of a single material, but a particle of a core-shell structure with different electrical conductivity coefficients and dielectric constants for each layer, assumes the particle as a particle of a core-shell structure in Equation 1, calculates a complex permittivity of a core-shell structure particle through the following Equation 2 to calculate a value of Equation 1, and examines a dielectric constant of the mobile medium and a dielectrophoretic force and a moving direction according to the frequency of the applied power.

$$\\ \begin{matrix}{ε}_{p}^{{}_{} *} = {ε}_{2}^{{}_{} *} \frac{{( \frac{{R}_{2}}{{R}_{1}} )}^{3} + 2 ( \frac{{ε}_{1}^{{}_{} *} - {ε}_{2}^{{}_{} *}}{{ε}_{1}^{{}_{} *} + 2 {ε}_{2}^{{}_{} *}} )}{{( \frac{{R}_{2}}{{R}_{1}} )}^{3} - ( \frac{{ε}_{1}^{{}_{} *} - {ε}_{2}^{{}_{} *}}{{ε}_{1}^{{}_{} *} + 2 {ε}_{2}^{{}_{} *}} )} & [ Equation 2 ]\end{matrix}$$

In Equation 2, R₁ denotes a radius of a core portion, R₂ denotes a radius of the core-shell particle, and ε₁* and ε₂* are complex permittivities of the core portion and a shell portion, respectively.

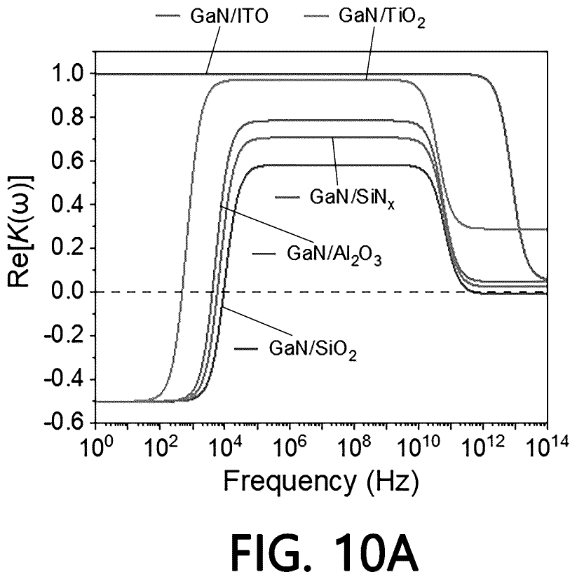

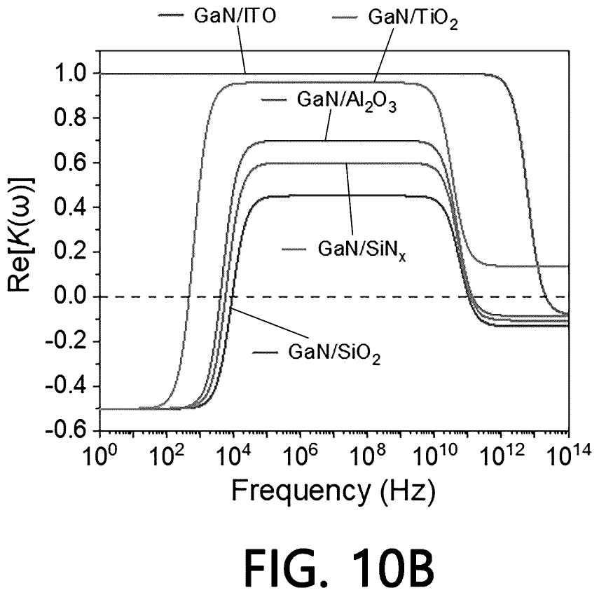

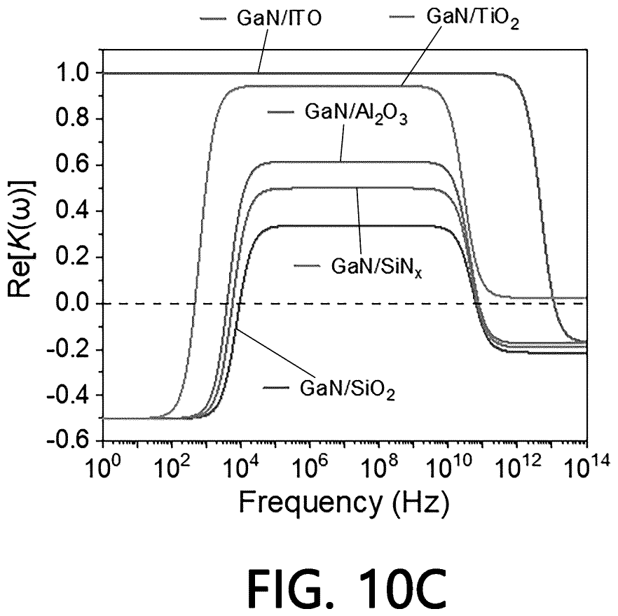

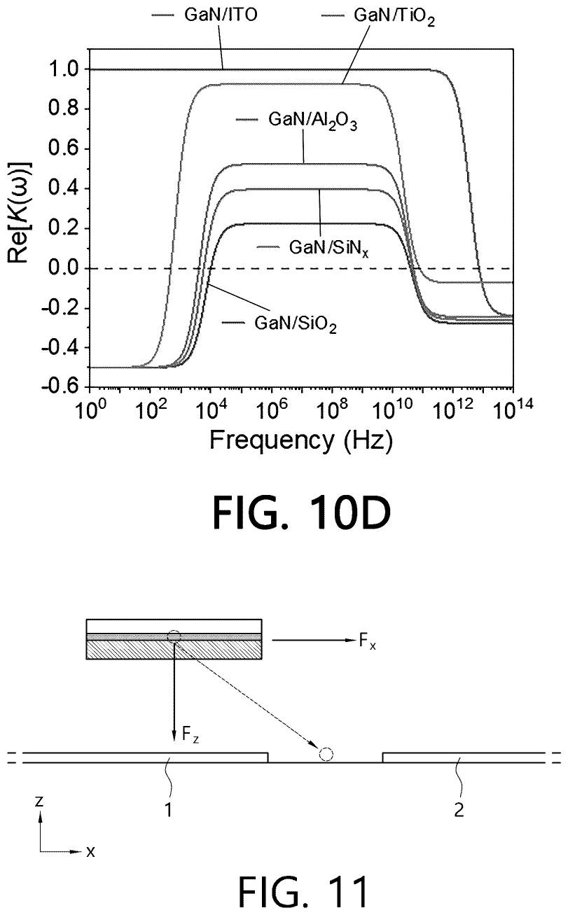

To describe with reference to FIGS. 10A to 10D, FIGS. 10A to 10D show a real part of the value according to Equation 1 for the dielectric constant of the mobile medium and each frequency of the applied power with respect to a spherical core-shell particle with a radius of 430 nm, which is implemented by fixing the core portion to GaN with a radius of 400 nm and changing the shell portion to ITO, SiO₂, SiNₓ, Al₂O₃, and TiO₂, each with a thickness of 30 nm. Specifically, as confirmed in FIGS. 8 and 9, GaN and ITO each have pDEP values approaching one in a significantly large high frequency band when GaN and ITO are single particles, and FIGS. 10A to 10D show that, even in the case of particles of a core-shell structure in which ITO is disposed as a shell portion on GaN that is the core portion, GaN and ITO still each have a large pDEP value close to one. In addition, in the case of particles of the core-shell structure in which TiO₂ is disposed as the shell portion GaN that is the core portion, it can be seen that TiO₂ is influenced by GaN, which has a large pDEP value when it is a single particle, moves to have a pDEP value that is greater than a pDEP value when TiO₂ is a single particle, and a frequency band with a pDEP value is reduced compared to that when TiO₂ is a single particle. On the other hand, in the case of SiO₂, SiNₓ, and Al₂O₃ which each have nDEP value in single particles, in the core-shell structure particle disposed as a shell of the core portion that is GaN, GaN is changed to a pDEP value in some frequency ranges, for example, a frequency range of 10 GHz or lower in which GaN has a pDEP value, more preferably 1.0, due to an influence of a large pDEP value of GaN. Therefore, when these results are combined, when a group III-nitride compound, for example, a GaN LED device, is provided with a material layer as the outermost layer, the GaN LED device has a frequency band with a pDEP value, although there is a difference in size.

Through these results, when the electrical conductivities and dielectric constants of the layers (or surfaces) constituting the LED device are adjusted materially and/or structurally, the LED device may move to the mounting electrode at a predetermined frequency, and further, it is possible to implement a mounting form in which the first surface B or the second surface T of the LED device, predominant to the side surface, move toward and come into contact with the upper surface of the mounting electrode. Consequently, a drivable mounting ratio can be increased, an increase in brightness can be achieved, and a non-light emission problem occurring when the side surface S of the LED device comes into contact with the mounting electrode can be minimized. Furthermore, when a specific one surface of the first surface B and the second surface T is mounted to come into contact with the upper surface of the mounting electrode, it is possible not only to increase a ratio of LED devices emitting light to mounted LED devices but also to select DC power as the driving power so that the freedom of power selection can increase, and a higher brightness can be achieved when the DC power is selected.

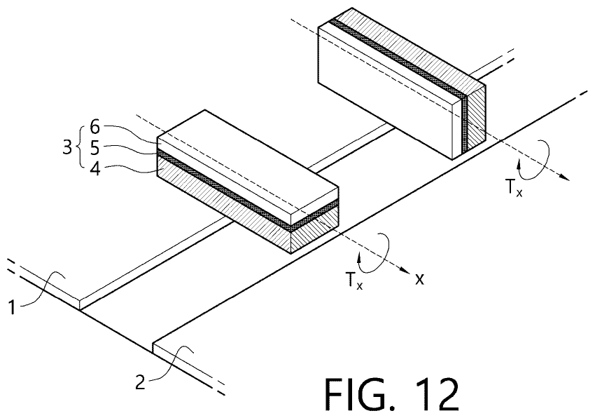

To this end, as shown in FIG. 11, even when the LED device 3 has a positive Re[K(ω)] in Equation 3 and thus moves toward a high electromagnetic field formed by power applied to the lower electrodes 1 and 2, as shown in FIG. 12, rotation is needed to direct any one surface of the first surface B and the second surface T, not the side surface toward the lower electrodes 1 and 2.

Therefore, as shown in FIGS. 11 and 12, the second cover layer 52 performs a function of generating a rotational torque T_{X} about an imaginary rotation axis X passing through the center of the LED device in the major axis direction of the LED device while the LED device moves to the lower electrodes 1 and 2 forming an electric field in an X-axis direction and a Z-axis direction and directing any one surface of the first surface B and the second surface T, not the side surface, toward the lower electrodes 1 and 2. Consequently, the first surface B or the second surface T of the LED device 3 is mounted to come into contact with the upper surfaces of the lower electrodes 1 and 2, that is, a mounting ratio of drivable LED devices to the entire mounted LED devices can be increased. Furthermore, a selective mounting ratio in which a specific one surface of the first surface B and the second surface T of the LED device 3 is mounted to come into contact with the upper surface of the mounting electrode can be further increased.

To this end, the second cover layer 52 is assumed as a spherical core-shell particle in which the particle is used as a core portion of GaN and the second cover layer is used as a sell portion and may be formed of a material satisfying that a real part of a K(ω) value, which is calculated according to Equation 1 in at least a part of a frequency range within a range in which a frequency of the applied power is 10 GHz or lower, ranges from more than 0 to 0.72 or less, more preferably more than 0 and 0.62 or less in consideration of the dielectric constant of the mobile medium.

Since the second cover layer 52 has the real part of the K(ω) value with a positive number of more than 0 according to Equation 1 for a spherical core-shell particle in which the lowest layer having the first surface B is the core portion that is GaN and the second cover layer 52 is disposed as the shell portion, without hindering the movement of the LED devices 100, 100′, 101, and 102 toward the mounting electrode, it is possible to significantly improve the drivable mounting ratio among all the LED devices mounted on the mounting electrode and the selective mounting ratio in which a specific one surface of the first surface B and the second surface T is mounted to come into contact with the surface of the mounting electrode. When the second cover layer 52 with the real part of the K(ω) value according to Equation 1 being 0, a negative number, or more than 0.72 is provided on the side surface of the LED device, the drivable mounting ratio and the selective mounting ratio in which a specific one surface of the first surface B and the second surface T becomes a mounting surface (or contact surface) are reduced, and in particular, the selective mounting ratio can be significantly reduced (see Table 2).

Meanwhile, under the above-described conditions, the second cover layer 52, of which the real part of the K(ω) value according to Equation 1 satisfies more than 0 and 0.62 or less, exhibits an effect of increasing the drivable mounting ratio of the LED device and the selective mounting ratio in which a specific one surface of the first surface B and the second surface T selectively comes into contact with the mounting electrode and, simultaneously, increasing a good product mounting ratio that is a mounting ratio of a good product when the LED device is disposed on the lower electrode and then a driving electrode is formed above the disposed LED device through a subsequent process.

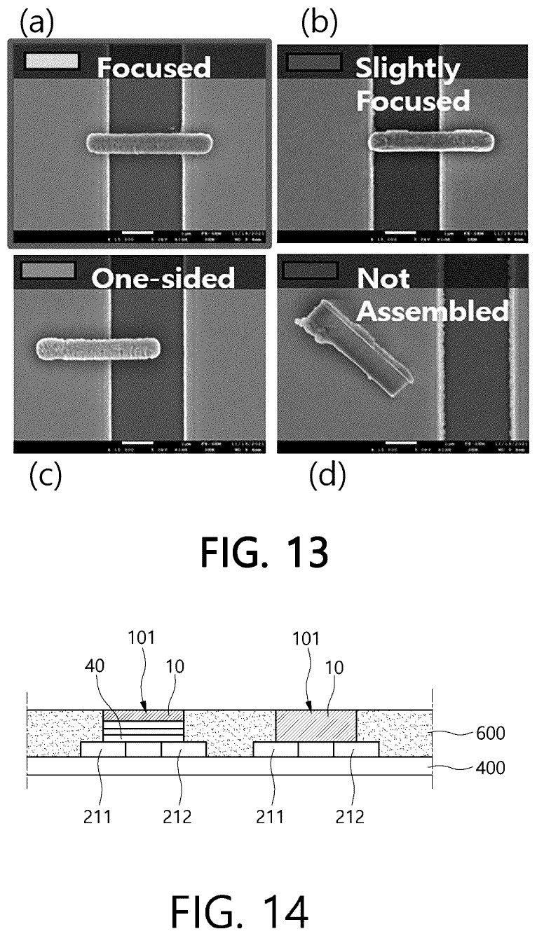

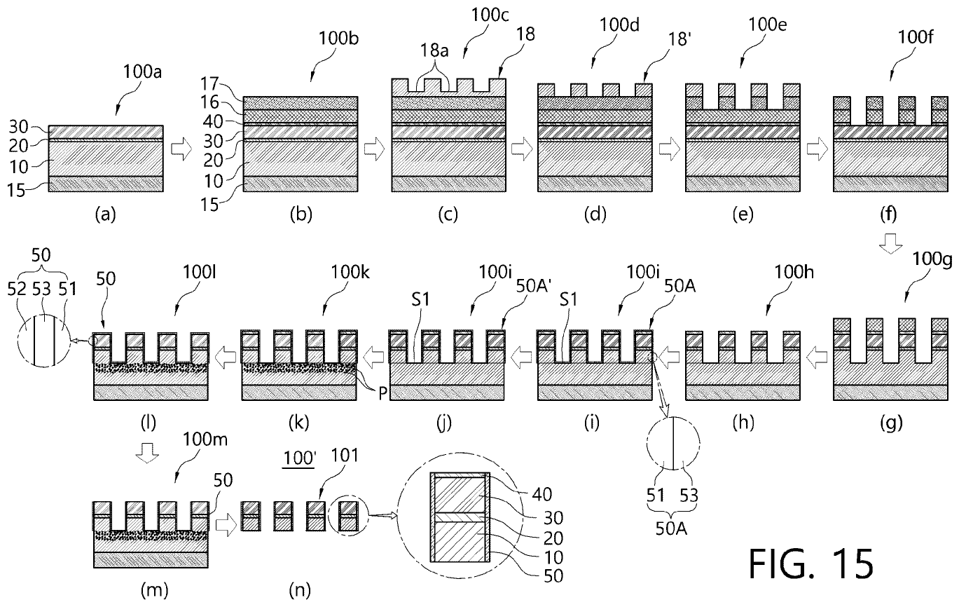

Specifically, to describe with reference to FIG. 13, even when the first surface B or the second surface T is aligned to come into contact with the lower electrodes, a mounting form may be shown that ends of the LED device are mounted to be positioned on surfaces of adjacent lower electrodes with a similar contact area as in FIG. 13A, the ends of the LED device are positioned on the surfaces of the adjacent lower electrodes and biased to and mounted on one of the surfaces of the adjacent lower electrodes as in FIG. 13B, or one end of the LED device is disposed to come into contact with the surface of one of the adjacent lower electrodes. In order for an upper electrode 301 (see FIG. 15), which becomes the driving electrode, to be formed while smoothly coming into contact with the upper surface of the LED device, it may be advantageous to have the mounting forms as shown in FIGS. 13A and 13B. However, the LED device provided with the second cover layer 52 of which the real part of the K(ω) value ranges from more than 0 to 0.62 or less may be undesirable because a ratio of the LED device in the mounting form shown in FIG. 13C increases significantly compared to an LED device without the second cover layer 52.

In addition, the second cover layer 52 may be formed to have a thickness ranging from 1 nm to 60 nm, and thus it may be more advantageous in achieving the objective of the present invention. When the thickness of the second cover layer 52 is less than 1 nm, a rotation of the LED device may not be properly induced under an electric field, and when the thickness of the second cover layer 52 is more than 60 nm, a manufacturing time and cost may increase.

In addition, when the LED devices 100, 100′, 101, and 102 are each provided with the second cover layer 52, of which the real part of the K(ω) value of more than 0 and 0.72 or less and, further, each have a difference in electrical conductivity constant and/or a dielectric constant between a bottom layer having the first surface B and a top layer having the second surface T due to material and/or structural adjustment, the drivable mounting ratio or the selective mounting ratio, which is the mounting ratio of drivably mounted LED devices among all the mounted LED devices, can be further increased. In order to describe the above description, the layers constituting the LED device will be first described.

Specifically, as shown in FIGS. 1 and 2, the LED device 100 is a device in which a plurality of layers including the photoactive layer 20 are stacked and may further include a conductive semiconductor layer.

A conductive semiconductor layer employed in a typical LED device used in lighting and a display may be used as the conductive semiconductor layers 10 and 30 without limitation. According to an exemplary embodiment of the present invention, the LED device 100 may include the first conductive semiconductor layer 10 and the second conductive semiconductor layer 30. In this case, any one of the first conductive semiconductor layer 10 and the second conductive semiconductor layer 30 may include at least one n-type semiconductor layer, and the other one may include at least one p-type semiconductor layer.

When the first conductive semiconductor layer 10 includes an n-type semiconductor layer, the n-type semiconductor layer is made of a semiconductor material with a composition formula of InₓAl_{y}Ga_{1-x-y}N (0≤x≤1, 0≤y≤1, and 0≤x+y≤1), for example, made of one or more selected from InAlGaN, GaN, AlGaN, InGaN, AlN, and InN and may be doped with a first conductive dopant (e.g., Si, Ge, or Sn). According to an exemplary embodiment of the present invention, a thickness of the first conductive semiconductor layer 10 including the n-type semiconductor layer may range from 0.2 μm to 3 μm, but the present invention is not limited thereto.

When the second conductive semiconductor layer 30 includes a p-type semiconductor layer, the p-type semiconductor layer is made of a semiconductor material with a composition formula of InₓAl_{y}Ga_{1-x-y}N (0≤x≤1, 0≤y≤1, and 0≤x+y≤1), for example, made of one or more selected from InAlGaN, GaN, AlGaN, InGaN, AlN, and InN and may be doped with a second conductive dopant (e.g., Mg). According to an exemplary embodiment of the present invention, a thickness of the second conductive semiconductor layer 30 including the p-type semiconductor layer may range from 0.01 μm to 0.35 μm, but the present invention is not limited thereto.

In addition, the photoactive layer 20 is formed between the first conductive semiconductor layer 10 and the second conductive semiconductor layer 30 and may be formed in a single or multiple quantum well structures. A photoactive layer employed in a typical LED device used in lighting and a display may be used as the photoactive layer 20 without limitation. In addition, a clad layer (not shown) doped with a conductive dopant may be formed above and/or below the photoactive layer 20, and the clad layer doped with a conductive dopant may be implemented as an AlGaN layer or an InAlGaN layer. In addition, materials such as AlGaN and AlInGaN may also be used as the photoactive layer 20. When an electric field is applied to the LED device, electrons and holes moving from the conductive semiconductor layers positioned above and below the photoactive layer combine to generate electron-hole pairs in the photoactive layer 20 so that light is emitted. According to an exemplary embodiment of the present invention, a thickness of the photoactive layer 20 may range from 30 μm to 300 μm, but the present invention is not limited thereto.

Meanwhile, the LED device 100 of FIGS. 1 and 2 is shown as including the first conductive semiconductor layer 10, the photoactive layer 20, and the second conductive semiconductor layer 30 as minimum components. In addition, it should be noted that other photoactive layers, conductive semiconductor layers, phosphor layers, hole block layers, and/or electrode layers may be further included above/below each layer.

Meanwhile, as described above, the LED device 100 in which the plurality of layers 10, 20, and 30 are stacked may be formed such that the first surface B or the second surface T among the plurality of surfaces of the LED device predominantly moves to come into contact with the upper surface of the lower electrode, and furthermore, materials and/or structures constituting the LED device may differ according to a position within the LED device so as to increase the drivable mounting ratio and the selective mounting ratio.

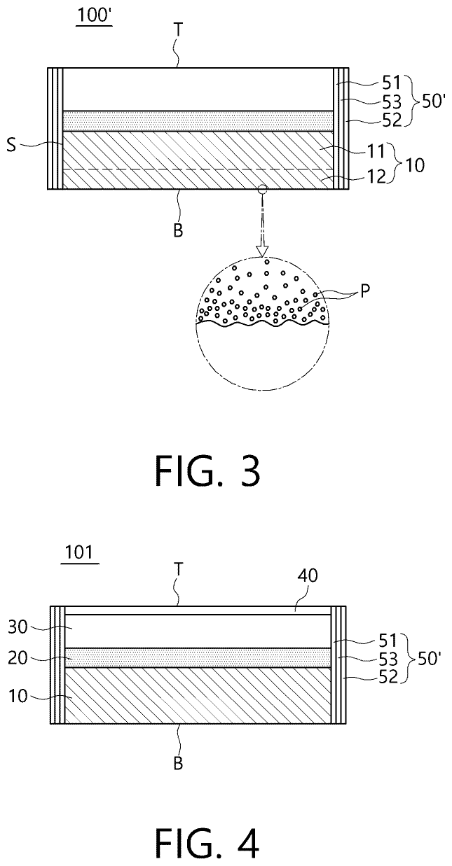

To describe with reference to FIG. 3, the LED device 100, has a structure containing a plurality of pores P in a region 12 of the first conductive semiconductor layer 10 extending from the first surface B to a predetermined thickness, and the remaining region 11 may not contain pores P. The structure containing the plurality of pores P has a lower dielectric property and lower electrical conductivity due to air contained in the pores P. Thus, the first conductive semiconductor layer 10 may have the materials and the structure different from those of the second conductive semiconductor layer 30 with the second surface T, which corresponds to the top layer. In addition, the structure containing the plurality of pores P has an advantage of increasing light emission efficiency by preventing light emitted from an inside of the LED device 100′ from being trapped and not being emitted due to internal reflection. Meanwhile, the structure containing the plurality of pores P may be formed in an n-type GaN portion exposed to an etching solution by etching an LED wafer to a thickness of a portion of an n-type GaN semiconductor with a shape and a size of the LED device and then perform electrochemical etching so as to separate the etched LED structure from the LED wafer. Korean Patent Application No. 10-2020-0189204 by the inventors of the present invention is incorporated as a reference of the LED device 100 of the present invention. Meanwhile, as an example, a diameter of the pore may range from of 1 nm to 100 nm.

Alternatively, according to another embodiment of the present invention, in order to increase the drivable mounting ratio and the selective mounting ratio, in the LED device, the bottom layer having the first surface B and the top layer having the second surface T are made of materials of which one or more of electrical conductivity coefficients and dielectric constants are different. Preferably, the electrical conductivity coefficients may be different. As an example, the electrical conductivity coefficient of the top layer having the second surface T may be greater than that of the bottom layer having the first surface B, more preferably, the electrical conductivity coefficient of the top layer is 10 times or more and preferably 100 times or more that of the bottom layer. In this way, it may be advantageous to achieve a further increased selective mounting ratio.

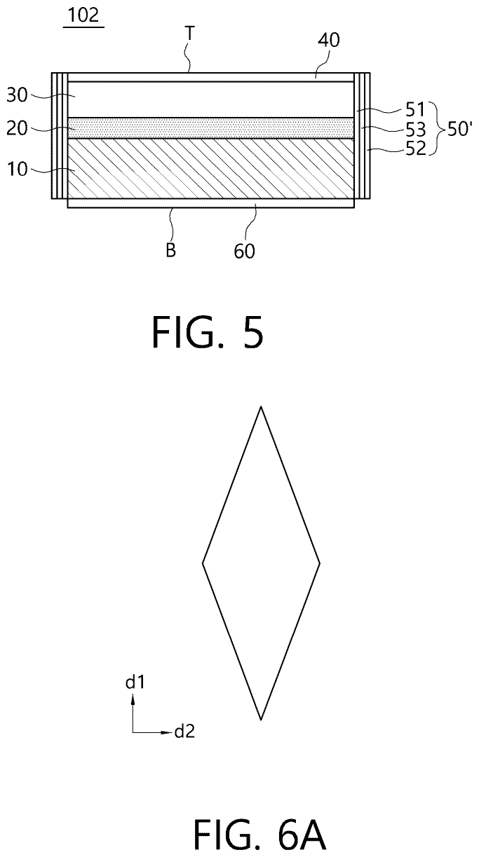

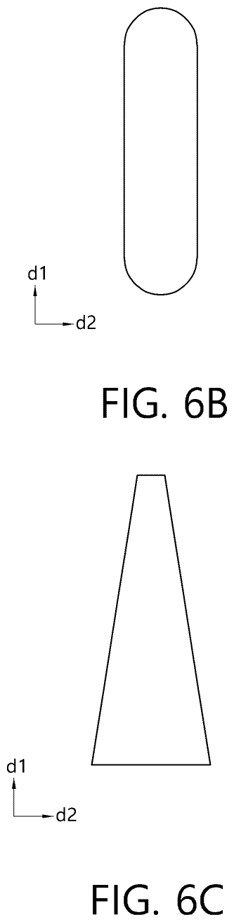

To describe with reference to FIGS. 4 and 5, as an example, in addition to the first conductive semiconductor layer 10, the photoactive layer 20, and the second conductive semiconductor layer 30, the LED devices 101 and 102 each include a selective alignment orientation layer 40 or a selective alignment rejection layer 60 as the top layer having the second surface T or the bottom layer having the first surface B of each of the LED devices 101 and 102 by arranging the selective alignment orientation layer 40 or the selective alignment rejection layer 60 on or below the second conductive semiconductor layer 30 and the first conductive semiconductor layer 10.

The selective alignment orientation layer 40 may be made of a material with greater electrical conductivity than the first conductive semiconductor layer 10. As a specific example, the selective alignment orientation layer 40 may be an electrode layer. A typical electrode layer provided in an LED device may be used as the electrode layer without limitation. As a non-limiting example, Cr, Ti, Al, Au, Ni, ZnO, AZO, ITO, oxides thereof or alloys thereof may be used alone or in combination. Preferably, in order to increase the selective mounting ratio in which the second surface T comes into contact with the upper surface of the lower electrode compared to other electrode layer materials, the electrical conductivity coefficient of the selective alignment orientation layer 40 may be 10 times or more and preferably 100 times or more the electrical conductivity coefficient of the first conductive semiconductor layer 10. In this way, it may be advantageous to achieve a further increased selective mounting ratio. In addition, when the selective alignment orientation layer 40 is an electrode layer, a thickness may range 10 nm to 500 nm, but the present invention is not limited thereto.

Alternatively, the selective alignment rejection layer 60 may be made of a material with an electrical conductivity that is lower than an electrical conductivity of the second conductive semiconductor layer 30. As an example, the selective alignment rejection layer 60 may be an electron retardation layer having an electron delay function. That is, since the LED device is implemented such that the thickness in a stacking direction of each layer is smaller than the length, the thickness of the n-type GaN layer is inevitably relatively thin. Conversely, since electron drift velocity is greater than hole drift velocity, combination locations of electrons and holes occur at the second conductive semiconductor layer 30 rather than the photoactive layer 20 so that light emission efficiency can be degraded. The selective alignment rejection layer 60, which is an electron retardation layer, may balance the number of recombined holes and electrons in the photoactive layer 20 to prevent the light emission efficiency from being degraded and selectively increase a probability that the second surface T among several surfaces comes into contact with the mounting electrode. Preferably, the electrical conductivity coefficient of the top layer, for example, the second conductive semiconductor layer 30 (or the selective alignment orientation layer 40), may be 10 times or more and preferably 100 times or more the electrical conductivity coefficient of the selective alignment rejection layer 60. In this way, it may be advantageous to achieve a further improved selective mounting ratio in which the second conductive semiconductor layer 30 (or the selective alignment orientation layer 40) comes into contact with the upper surface of the lower electrode.

The electron retardation layer may include one or more selected from the group consisting of, for example, CdS, GaS, ZnS, CdSe, CaSe, ZnSe, CdTe, GaTe, SiC, ZnO, ZnMgO, SnO₂, TiO₂, In₂O₃, Ga₂O₃, Si, poly(paraphenylene vinylene) and its derivatives, polyaniline, poly(3-alkylthiophenc), and poly(paraphenylene). Alternatively, when the first conductive semiconductor layer 10 is a doped n-type III-nitride semiconductor layer, the electron retardation layer may be made of a III-nitride semiconductor whose doping concentration is lower than that of the first conductive semiconductor layer 10. In addition, a thickness of the electron retardation layer may range from 1 nm to 100 nm, but the present invention is not limited thereto, and the thickness may be appropriately changed by considering the material of the n-type conductive semiconductor layer and the material of the electron retardation layer.

According to one embodiment of the present invention, as shown in FIGS. 3 to 5, a cover layer 50′ may further include a third cover layer 53 serving as a resistance layer against dry and wet etching between the first cover layer 51 and the second cover layer 52.

The second cover layer 52 should satisfy a predetermined physical property in order to generate a rotational torque of the LED device within an electric field, and a material satisfying the physical property may be generally vulnerable to dry and wet etching.

Specifically, even when the second cover layer 52 is provided, a mounting defect in which the side surface of the LED device comes into contact with the lower electrode may occur. As described above, in a dry and/or wet etching applied in a subsequent process after self-aligning the LED device on the lower electrode, the side surface of the LED device with such a mounting defect may be partially or completely exposed even though the second cover layer 52 and the first cover layer 51 are present. To describe the above description in detail with reference to FIG. 14, among LED devices 101 self-aligned on lower electrodes 211 and 212 through dielectrophoresis, a right LED device 101 has a mounting defect in which side surfaces of the right LED device come into contact with the lower electrodes 211 and 212. After the self-alignment of the LED device 101 is completed, a process of forming an upper electrode is necessarily performed in order to drive the mounted LED device 101. A passivation layer 600 is formed as a planarized layer to facilitate the formation of the upper electrode and to insulate the lower electrodes 211 and 212 and the mounted LED device 101. However, since the passivation layer 600 is formed uniformly from the top of the mounted LED device in a downward direction, the upper surface of the mounted LED device 101 is inevitably coated with a material forming the passivation layer 600. The material forming the passivation layer 600 with which the upper surface of LED device 101 is coated may hinder an electrical contact between an upper electrode to be formed and the LED device 101. Therefore, an etching process of removing the material forming the passivation layer 600 with which the upper surface of the mounted LED device 101 is coated is inevitably performed. Like the LED device 101 mounted on the right side of FIG. 14, the side surface of the LED device 101 with the mounting defect becomes the upper surface of the mounted LED device 101, the second cover layer 52 and the first cover layer 51 provided on the side surface of the LED device are not strong enough to withstand dry etching and/or wet etching so that a part or all of the second cover layer 52 and the first cover layer 51 may be peeled off or damaged during the etching process. In this case, when driving power is applied, a current may flow to the side surface of the LED device, in which the mounting defect occurs, exposed through the upper electrode so that an electrical short circuit or a leakage current may occur.

In addition, the LED device according to one embodiment of the present invention undergoes a process of immersing a wafer in an acidic electrolyte and performing electrochemical etching by applying power to the wafer as a process of forming a plurality of pores at a boundary between the wafer and the LED structure to be separated during a manufacturing process which will be described. In the electrochemical etching, damage to and delamination of a part or all of the second cover layer 52 and the first cover layer 51 may occur. In this case, the functions of the second cover layer 52 and first cover layer 51 cannot fully operate.

However, since the third cover layer 53 serves as a resistance layer in the manufacturing process of the LED device or in the etching process performed after the self-aligning and mounting of the LED device, the side surfaces of the LED devices 101 and 102 may be maintained not to be exposed and, even when a mounting defect occurs, an electrical short circuit or leakage current can be prevented from occurring when the driving power is applied.

The third cover layer 53 may be formed of a known material with resistance against a plurality of etching processes performed during the typical LED manufacturing process or electrode assembly manufacturing. Preferably, when etching is performed at an etch rate B (nm/min) of the third cover layer 53, the material may be a material satisfying an etch ratio of 2.0 or more, which is a ratio of the etch rate (nm/min) B to an etch rate A (nm/min) of the second cover layer 52.

However, more preferably, a material of the third cover layer 53 is selected as an inorganic and/or organic material with an etch rate of 30 nm/min or less under a dry etching condition using halogen plasma. When the third cover layer 53 is implemented using a material whose etch speed is more than 30 nm/min, the third cover layer 53 can be difficult to serve as a resistance layer in the etching process.

In addition, a thickness of the third cover layer 53 may range from 1 nm to 30 nm. When the thickness is less than 1 nm, since the third cover layer may be fully etched during the etching process, the third cover layer cannot serve as an etch resistance layer, and when the thickness is more than 30 nm, the manufacturing process cost can increase.

The LED devices 100, 100′, 101, and 102 according to the present invention each have an light emitting area improved by stacking several layers such as the conductive semiconductor layers 10 and 30 and the photoactive layer 20 in the thickness direction and forming the length to be longer than the thickness. In addition, although an exposed area of the photoactive layer 20 increases slightly according to an increase in the length, since thicknesses of layers to be implemented in the process of manufacturing LED devices are thin, an etching depth is shallow and defects occurring on the exposed surfaces of the photoactive layer 20 and the conductive semiconductor layers 10 and 30 are ultimately reduced in the etching process so that it is advantageous in minimizing or preventing reduction in light emission efficiency due to the surface defects, and the generated surface defects are removed/repaired through the first cover layer 51, and thus it is advantageous to achieve improved light emission efficiency.

In addition, a ratio of an overall total length to a thickness of each of the LED devices 100, 100′, 101, and 102 may be, for example, 3:1 or more, more preferably 6:1 or more, and thus the length is greater than the thickness. In this way, there is an advantage that the LED devices 100, 100′, 101, and 102 may each be more easily self-aligned on the lower electrodes 211 and 212, which are mounting electrodes, using a dielectrophoretic force through an electric field. When the ratio of the overall length to the thickness of the LED device 100 is less than 3:1 so the length is reduced, it can be difficult to self-align the LED devices on the mounting electrode using the dielectrophoresis force through the electric field, and the LED device is not fixed on the mounting electrode so that an electrical contact short circuit may occur due to a process defect. However, the ratio of the overall length to the thickness may be 15:1 or less. In this way, it may be advantageous in achieving the objective of the present invention, such as optimizing a turning force that can be self-aligned using an electric field.

Meanwhile, a d1-d2 plane in each of the LED devices 100, 100′, 101, and 102 is shown as a rectangular shape in FIGS. 1 to 5, but the present invention is not limited thereto. It should be noted that the shape of the d1-d2 plane may have shapes including general quadrangular shapes such as a rhombic shape and a trapezoid shape as shown in FIGS. 7A and 7C, an ellipse, and a closed curve shape formed of curves and straight lines as shown in FIG. 7B.

In addition, the LED devices 100, 100′, 101, and 102 according to one embodiment of the present invention each have the length and a width of micro- or nano-scale. As an example, the length of each of the LED devices 100, 100′, 101, and 102 may range from 1 μm to 10 μm and the width thereof may range 0.25 μm to 1.5 μm. In addition, the thickness may range from 0.1 μm to 3 μm. The length and the width may have different standards according to the shape of the plane. As an example, when the x-y plane is a rhombus or parallelogram, one of two diagonals may be a length and the other may be a width, and when the x-y plane is a trapezoid, the longer of a height, a top side, and a bottom side may be the length, and the shorter perpendicular to the longer may be the width. In addition, when the shape of the x-y plane is an ellipse, a major axis of the ellipse may be the length, and a minor axis perpendicular to the major axis may be the width.

The LED devices 100, 100′, 101, and 102 according to one embodiment of the present invention may be used as light sources for various purposes throughout the industry. For example, the light sources may be various types of LED lights such as those for household/vehicle use, light emission sources of various displays such as backlight units used in liquid crystal displays (LCDs) or such as active displays, or parts constituting medical devices, beauty devices, and various optical devices. In addition, in a method of implementing the light source, a method of mounting a device on a mounting electrode through dielectrophoresis can be useful.

The LED devices 100, 100′, 101, and 102 according to one embodiment of the present invention may be manufactured through a manufacturing method which will be described below, but the present invention is not limited thereto.

The LED device according to one embodiment of the present invention is manufactured by performing operation (1) of forming an LED wafer on which a plurality of LED structures are formed, operation (2) of forming a cover layer to surround an etched exposed surface of each of the plurality of LED structures to allow an upper surface of the LED wafer between adjacent LED structures to the outside, and operation (3) of separating the plurality of LED structures from the LED wafer.

To describe with reference to FIG. 15, in operation (1), an LED wafer 100h on which a plurality of LED structures are formed is formed (see FIGS. 15A to 15H).

Specifically, operation (1) may be performed through operation 1-1) preparing an LED wafer 100a which includes a substrate 15, a doped n-type III-nitride semiconductor layer 10, a photoactive layer 20, and a p-type III-nitride semiconductor layer 30 and on which the layers 10, 20, and 30 are stacked on the substrate 15 (see FIG. 15A), operation 1-2) of patterning an upper portion of the LED wafer 100a to allow a plane perpendicular to a direction in which the layers are stacked in the individual LED structure to have a desired shape and a desired size (see FIGS. 15B and 15C), and operation 1-3) of vertically etching the doped n-type III-nitride semiconductor layer to at least a portion of a thickness and forming an LED wafer 100h1 on which the plurality of LED structures are formed (see FIGS. 15D to 15H).

The LED wafer 100a prepared in step 1-1) may be manufactured to have a pre-designed thickness or a commercially available wafer which can be used without limitation. In addition, since the n-type III-nitride semiconductor layer is etched to have the desired thickness and then the remaining etched LED structures on the LED wafer may be separated through operation (3) which will be described below, the thickness of the n-type III-nitride semiconductor layer 10 in the LED wafer is also not limited, and the presence or absence of a separate sacrificial layer may not be considered when the LED wafer is selected. In addition, each layer in the LED wafer 100a may have a c-plane crystal structure. In addition, the LED wafer 100a may have undergone a cleaning process, and the cleaning process may appropriately employ a typical wafer cleaning solution and a cleaning process, and thus the present invention is not particularly limited thereto. The cleaning solution may be, for example, isopropyl alcohol, acetone, and hydrochloric acid, but the present invention is not limited thereto.

Next, before performing operation 1-2), an operation of forming a first electrode layer, which is the selective alignment orientation layer 40, on the p-type III-nitride semiconductor layer 30 may be performed. The first electrode layer may be formed through a typical method of forming an electrode on a semiconductor layer. As an example, the first electrode layer may be formed by deposition through sputtering. As described above, a material of the first electrode layer may be, for example, ITO, and the first electrode layer may be formed to have a thickness of about 150 nm. The first electrode layer may further undergo a rapid thermal annealing process after the deposition process. As an example, the first electrode layer may be treated at a temperature of 600° C. for 10 minutes, and the temperature and the time may be adjusted appropriately by considering the thickness and the material of the electrode layer, and thus the present invention is not particularly limited thereto.

Next, in operation 1-2), the upper portion of the LED wafer may be patterned to allow the plane perpendicular to the direction in which the layers are stacked in an individual LED structure to have a desired shape and a desired size (see FIGS. 15B and 15C). Specifically, a mask pattern layer may be formed on the upper surface of the first electrode layer, the mask pattern layer may be formed using a known method and a known material used when the LED wafer is etched, and a pattern of the pattern layer may be formed by appropriately applying a typical photolithography method or a nano imprinting method.

Specifically, the mask pattern layer may be a stacked body of a first mask layer 16, a second mask layer 17, and a resin pattern layer 18′, which form a predetermined pattern on the first electrode layer. To briefly describe a method of forming the mask pattern layer, as an example, the first mask layer 16 and the second mask layer 17 are formed on the first electrode layer through deposition, the resin layer 18, which is the origin of the resin pattern layer 18′, is formed on the second mask layer 17 (see FIGS. 15B and 15C), a residual resin portion 4a of the resin layer 18 is removed by a typical method such as reactive ion etching (RIE) (see FIG. 15D), and the second mask layer 17 and the first mask layer 16 are sequentially etched along the pattern of the resin pattern layer 18′ (see FIGS. 15E and 15F). In this case, the second mask layer 17 may be a metal layer such as aluminum or nickel, and the first mask layer 16 may be, for example, formed of silicon dioxide, and the second mask layer 17 and the first mask layer 16 may be etched by inductively coupled plasma (ICP) and RIE. Meanwhile, when the first mask layer 16 is etched, the resin pattern layer 18′ may also be removed (see FIG. 15F).

Meanwhile, the resin layer 18, which is the origin of the resin pattern layer 18′, may be formed through, for example, a nano imprinting method, and a wafer stacked body 100c on which the resin layer 18 is formed may be implemented by manufacturing a mold corresponding to a desired pattern mold, filling the mold with a resin to form the resin layer 18, transferring the resin layer 18 to position the resin layer 18 on a wafer stacked body 100b on which the second mask layer 17 is formed, and removing the mold.

Meanwhile, the method of forming the pattern through the nano imprinting method has been described, but the present invention is not limited thereto. The pattern may be formed through photolithography using a known photosensitive material or through known laser interference lithography or electron beam lithography.

Thereafter, as shown in FIG. 15G, an LED wafer 100g on which LED structures are formed may be manufactured by etching the n-type III-nitride semiconductor layer 10 to a predetermined thickness along the patterns of the mask pattern layers 2 and 3 formed on the first electrode layer in a direction perpendicular to a surface of an LED wafer 100f. In this case, the etching may be performed through a typical dry etching method such as ICP or a KOH/TAMH wet etching method. In the etching process, the second mask layer 17, which is made of Al constituting the mask pattern layer, may be removed. Thereafter, an LED wafer 100h on which the plurality of LED structures that are targets of operation (1) according to the present invention are formed may be manufactured by removing the first mask layer 16, which is made of silicon dioxide constituting the mask pattern layer present on the first electrode layer of each LED structure within the LED wafer 100g.

Then, in operation (2), an operation of forming a cover layer, which surrounds the etched exposed surface of each of the plurality of LED structures and exposes the upper surface of the wafer between adjacent LED structures to the outside, is performed.

First, in operation 2-1), the first cover layer 51 and the third cover layer 53 may be sequentially formed on the LED wafer 100h on which the plurality of prepared LED structures (see FIG. 15I), and as preprocessing of operation (3), which will be described below, an etching process may be performed to expose an upper surface S1 of the wafer between adjacent LED structures to the outside so as to enable electrochemical etching (see FIG. 15J).

Meanwhile, by performing operation 2-1), only a partial cover layer 50A including the first cover layer 51 and the third cover layer 53 is formed on the etched exposed surface of the LED structure, and the second cover layer 52 disposed on the outermost side is not formed. This is to prevent damage and delamination due to an acidic solution applied during the electrochemical etching which will be described below. The electrochemical etching is performed in a state in which the third cover layer 53 of the partial cover layer 50A positioned at the outermost side to prevent infringement of the first cover layer 51, and the second cover layer 52 is formed after the electrochemical etching is performed so that it is advantageous for each layer in the finally formed cover layer 50 to exhibit a complete form and a function without being infringed.

Then, in step 2-2), as preprocessing of separating the LED structure, the electrochemical etching is performed to form a plurality of pores at a boundary between the LED structure and the wafer (see FIG. 15K).

Specifically, in the electrochemical etching, the prepared LED wafer 100i is impregnated with an electrolyte and is electrically connected to one terminal of a power source, the remaining terminal of the power source is connected to an electrode impregnated with the electrolyte, and power is applied so that the plurality of pores P may be formed in the upper portion of the LED wafer, which corresponds to the doped n-type III-nitride semiconductor layer positioned between the LED structures. In this case, the pore P may begin to be formed from the upper surface S1 of the LED wafer, which is the doped n-type III-nitride semiconductor layer brought into direct contact with the electrolyte, and formed as the doped n-type III-nitride corresponding to the lower portion of each of the plurality of LED structures in the thickness direction and in a horizontal direction.

The electrolyte used in operation 2-2) may be preferably oxalic acid, and specifically, may include one or more selected from the group consisting of oxalic acid, phosphoric acid, sulfurous acid, sulfuric acid, carbonic acid, acetic acid, chlorous acid, chloric acid, hydrobromic acid, nitrous acid, and nitric acid. In addition, platinum (Pt), carbon (C), nickel (Ni), or gold (Au) may be used as the electrode. As an example, the electrode may be a Pt electrode. In addition, as an example, a voltage ranging from 3 V to 30 V may be applied as power for 1 minute to 24 hours in operation 2-2). In this way, the pore P may be smoothly formed in the doped n-type III-nitride semiconductor layer corresponding to the lower portion of each of the plurality of LED structures, and thus the LED structure may be more easily separated from the LED wafer through operation (3) which will be described below. Meanwhile, the strength and time of the power applied in operation 2-2) may be appropriately changed by considering a size of a region where the pores are to be formed, and a doping content in the doped n-type III-nitride semiconductor layer.

Thereafter, in operation 2-3), an operation of forming the second cover layer 52 on the partial cover layer 50A to form the cover layer 50 surrounding the etched side surface of the LED structure is performed (see FIG. 15I). The second cover layer 52 may be deposited through a known method by considering a type of material to be formed, and thus the present invention is not particularly limited thereto. In addition, after the second cover layer 52 is formed, an etching process may be performed to remove a second cover layer formation material, with which the upper surface S1 of the LED wafer between the LED structure and the upper surface of the LED structure is coated, rather than on the side surface of the LED structure. The etching process may be performed through a known method by considering the type of second cover layer formation material, and thus the present invention is not particularly limited thereto.

Next, in operation (3), an operation of separating the LED structure from the LED wafer is performed (see FIGS. 15M and 15N).

In operation (3), the LED structure may be separated using the plurality of pores P formed in advance at the boundary between the LED structure and the LED wafer. A known method may be used in the separation without limitation as long as it can collapse the pores. As an example, the separation may be performed by directly and physically collapsing the pores by applying ultrasound to the LED wafer or by immersing the LED wafer 100m on which the pores P are formed in a solvent and indirectly applying ultrasound to the LED wafer. However, the method of collapsing pores using a physical external force caused by only ultrasound does not allow the pores to be collapsed smoothly, and when the pores are formed excessively for smooth collapse, the pores may be formed in a second portion b of the LED structure so that side effects of deteriorating quality of the LED structure may be caused.

Thus, according to one embodiment of the present invention, operation (3) may be performed using sonochemistry. Specifically, the LED wafer 100m is immersed with a bubble-forming solution (or solvent), ultrasound is applied to the bubble-forming solution (or solvent) to generate and grow bubbles in the bubble-forming solution (or solvent), and the generated bubbles are moved to infiltrate into the pores P of a first portion a so that, and the plurality of LED structures may be easily separated from the LED wafer through a pore collapse mechanism in which the pores P are collapsed due to an external force generated upon a burst of unstable bubbles with a high temperature and a high pressure, which infiltrate into the pores P.

A solution (or solvent) may be used as the bubble-forming solution (or solvent) without limitation as long as it can generate bubbles when ultrasound is applied and grow the bubbles to have a high pressure and a high temperature. The bubble-forming solution (or solvent) with a vapor pressure of 100 mmHg (20° C.) or less, as an example, a vapor pressure of 80 mmHg (20° C.) or less, 60 mmHg (20° C.) or less, 50 mmHg (20° C.) or less, 40 mmHg. (20° C.) or less, 30 mmHg (20° C.) or less, 20 mmHg (20° C.) or less, or 10 mmHg (20° C.) or less may be used. As an example, the bubble-forming solution may be one or more selected from the group consisting of gamma-butyl lactone, propylene glycol methyl ether acetate, methylpyrrolidone, and 2-methoxyethanol.

In addition, a wavelength of the ultrasound applied in operation (3) may be applied at a frequency capable of growing and collapsing bubbles in a region in which sonochemistry is caused, specifically, a localized hot spot in which generates a high pressure and a high temperature when the bubbles collapse. As an example, the frequency may range from 20 kHz to 2 MHz, and an application time of the applied ultrasound may range from 1 minute to 24 hours. In this way, the LED structure may be easily separated from the LED wafer.

Meanwhile, the LED devices 100, 100′, 101, and 102 according to one embodiment of the present invention may be implemented using an ink composition necessary to apply the method of mounting the LED device on the mounting electrode through dielectrophoresis using an electric field for mass production. The ink composition includes the plurality of LED devices according to one embodiment of the present invention in a mobile medium. A mobile medium contained in a typical ink composition may be used as the mobile medium without limitation, and specifically, may be appropriately selected in consideration of a used printing method and device. Additionally, the mobile medium may have an appropriate dielectric constant to have a dielectrophoretic force for moving the implemented LED device toward the mounting electrode during dielectrophoresis. The mobile medium may have a dielectric constant of 10.0 or more. As another example, the mobile medium may have a dielectric constant of 30 or less. As still another example, the mobile medium may have a dielectric constant of 28 or less. As an example, the mobile medium may be acetone or isopropyl alcohol. In addition, the ink composition may further include an additive which is typically added in consideration of a printing method and device, and the present invention is not particularly limited thereto.

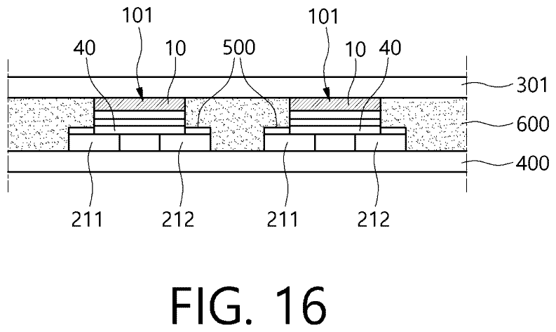

In addition, to describe with reference to FIGS. 3 and 16, the present invention includes an LED electrode assembly electrically connected to the lower electrodes 211 and 212, in which the first surface B and the second surface T of each of the plurality of LED devices 101 according to one embodiment of the present invention becomes different electrodes, for example, mounting electrodes, and the upper electrode 301.

The lower electrodes 211 and 212 may be disposed on a base material 400. The base material 400 may be a typical substrate or a planarized layer. The base material 400, the lower electrodes 211 and 212, and the mounted LED devices 101 may be planarized by the passivation layer 600. In addition, the upper electrode 301 in contact with the upper surface of the mounted LED device 101 is included, and an ohmic contact layer 500 for improving the electrical contact characteristics between the lower electrodes 211 and 212 and the LED device 101 may be further provided.

According to one embodiment of the present invention, the LED electrode assembly may satisfy a drivable mount ratio, in which the first surface B or the second surface T among the various surfaces of the LED device 101 is mounted to come into contact with the upper surfaces of the lower electrodes 211 and 212, of 65% or more due to the second cover layer 52 provided in the LED device 101, preferably 70% or more, more preferably 75% or more, even more preferably 80% or more, even more preferably 90% or more, or even more preferably 95% or more. In this way, by minimizing a case in which the LED device is not mounted or the side surfaces is mounted, excellent brightness can be achieved and manufacturing costs can be reduced by reducing the number of wasted LED device.

In addition, due to the second cover layer 52, the selective mount ratio, in which only one side of the first surface B and the second surface T of each of the plurality of LED devices 101 is selectively mounted toward the mounting electrode and comes into contact with the upper surface of the mounting electrode, can be further improved. In relation to the selective mount ratio, based on 120 devices at a frequency of 10 kHz and under a power condition of 40 Vpp, the LED device according to one embodiment of the present invention may be formed to satisfy the selective mount ratio, in which only one side of the first surface B and the second surface T of each of the plurality of LED devices 101 is selectively mounted toward the mounting electrode and comes into contact with the upper surface of the mounting electrode, of 70% or more, more preferably 85% or more, even more preferably 90% or more, and even more preferably 93% or more. In this way, a driving rate and brightness of the mounted LED device can be increased. In particular, when a contact ratio of a specific surface increases, an application width in which the driving power may be selected as DC power rather than AC power not only expands, but also it may be advantageous to implement increased brightness according to the use of DC power.

### EXAMPLES

The present invention will be described in more detail through the following examples, but the following examples do not limit the scope of the present invention, and this should be construed to help understanding of the present invention.

### Example 1

A typical LED wafer (Epistar), in which an undoped n-type III-nitride semiconductor layer, a Si-doped n-type III-nitride semiconductor layer (with a thickness of 4 μm), a photoactive layer (with a thickness of 0.15 μm), and a p-type III-nitride semiconductor layer (with a thickness of 0.05 μm) were sequentially stacked on a substrate, was prepared. ITO (with a thickness of 0.15 μm) as a selective alignment orientation layer, SiO₂ (with a thickness of 1.2 μm) as a first mask layer, and Ni (with a thickness of 80.6 nm) as the second mask layer were sequentially deposited on the prepared LED wafer, and then a spin on glass (SOG) resin layer, onto which a pattern of a rectangular shape was transferred, was transferred onto the second mask layer using a nano imprinting device. Thereafter, the SOG resin layer was cured using RIE, and the residual resin portion of the resin layer was etched through RIE to form a resin pattern layer. Then, the second mask layer was etched along the resin pattern layer using ICP, and the first mask layer was etched using RIE. Thereafter, a first electrode layer, the p-type III-nitride semiconductor layer, and the photoactive layer were etched using ICP, the doped n-type III-nitride semiconductor layer was etched down to a thickness of 0.5 μm, and an LED wafer, on which a plurality of LED structures (each having a long side of 4 μm, a short side of 750 nm, a height of 850 nm) from which the mask pattern layer was removed, was manufactured through KOH wet etching. Then, SiO₂ was deposited on the LED wafer, on which the plurality of LED structures were formed, with a thickness of 60 nm as a first cover layer, Al₂O₃ was deposited on the first cover layer with a thickness of 30 nm as a third cover layer, and materials of the first cover layer and the third cover layer formed on an upper surface of the LED wafer between the LED structures were removed through RIE to expose an upper surface of the doped n-type III-nitride semiconductor layer between the LED structures.

Afterwards, the LED wafer on which a partial cover layer formed of the first cover layer and the third cover layer was formed was impregnated with an electrolyte, which is a 0.3M oxalic acid solution, and then connected to an anode terminal of a power source, and a plurality of pores were formed from the surface of the doped n-type III-nitride semiconductor layer between the LED structures in a horizontal direction to a region corresponding to a lower end of the LED structure in a thickness direction after connecting a cathode terminal to a Pt electrode impregnated with the electrolyte and applying a voltage of 15V voltage for 5 minutes. Then, in Equation 1, a particle was assumed as a spherical core-shell particle with a radius of 430 nm, in which GaN has a radius of 400 nm as a core portion and a second cover layer has a thickness of 30 nm as a shell portion, the mobile medium was acetone with a dielectric constant of 20.7, and when a frequency of the applied power is in a frequency range of 10 kHz to 10 GHz, the second cover layer of SiO₂, whose a real part value of K(ω) according to Equation 1 was 0.336, was deposited with a thickness of 60 nm based on the side surface of the LED structure. Thereafter, the material of the second cover layer formed between the LED structures and on an upper surface of each LED structure was removed through RIE to expose an upper surface of the doped n-type III-nitride semiconductor layer between the LED structures, the LED wafer was immersed with a bubble-forming solution that was 100% gamma-butyrolactone, pores formed in the doped n-type III-nitride semiconductor layer were collapsed using bubbles generated by emitting ultrasound with a strength of 160 W at a frequency of 40 kHz for 10 minutes, and thus a plurality of individually separated LED devices were manufactured.

### Example 2

An LED device was manufactured in the same manner as in Example 1, except that the second cover layer was changed to a second cover layer of SiNₓ with a real part value of K(ω) of 0.501 according to Equation 1 under the same conditions.

### Example 3

An LED device was manufactured in the same manner as in Example 1, except that the second cover layer was changed to a second cover layer of TiO₂ with a real part value of K(ω) of 0.944 according to Equation 1 under the same conditions.

### Example 4

An LED device was manufactured in the same manner as in Example 1 without forming ITO as a selective alignment orientation layer.

### Example 5

An LED device was manufactured in the same manner as in Example 3 without forming ITO as a selective alignment orientation layer.

### Example 6

An LED device was manufactured in the same manner as in Example 1 by depositing the second cover layer without forming a plurality of pores, removing the material of the second cover layer formed on an upper portion of the LED structure through etching, and separating the LED structure from the LED wafer using a diamond cutter.

### Example 7

An LED device was manufactured in the same manner as in Example 6, except that the second cover layer was changed to a second cover layer of Al₂O₃ with a real part value of K(ω) of 0.616 according to Equation 1 under the same conditions.

### Example 8

An LED device was manufactured in the same manner as in Example 6, except that the second cover layer was changed to a second cover layer of TiO₂ with a real part value of K(ω) of 0.944 according to Equation 1.

### Example 9

An LED device was manufactured in the same manner as in Example 6 without forming ITO as a selective alignment orientation layer.

### Comparative Example 1

An LED device was manufactured in the same manner as in Example 1 without forming ITO and a second cover layer as a selective alignment orientation layer.

### Comparative Example 2

An LED device was manufactured in the same manner as in Example 6 without forming ITO and a second cover layer as a selective alignment orientation layer.

### Comparative Example 3

A typical LED wafer (Epistar), in which an undoped n-type III-nitride semiconductor layer, a Si-doped n-type III-nitride semiconductor layer (with a thickness of 4 μm), a photoactive layer (with a thickness of 0.45 μm), and a p-type III-nitride semiconductor layer (with a thickness of 0.05 μm) were sequentially stacked on a substrate, was prepared. SiO₂ (with a thickness of 1.2 μm) as a first mask layer, and Ni (with a thickness of 80.6 nm) as the second mask layer were sequentially deposited on the prepared LED wafer, and then an SOG resin layer, onto which a pattern of a 0.15 rectangular shape with the same size as in Equation 1 was transferred, was transferred onto the second mask layer using a nano imprinting device. Thereafter, the SOG resin layer was cured using RIE, and the residual resin portion of the resin layer was etched through RIE to form a resin pattern layer. Then, the second mask layer was etched along the resin pattern layer using ICP, and the first mask layer was etched using RIE. Thereafter, a first electrode layer, the p-type III-nitride semiconductor layer, and the photoactive layer were etched using ICP, the doped n-type III-nitride semiconductor layer was etched down to a thickness of 0.6 μm, and an LED wafer, on which a plurality of LED structures from which the mask pattern layer was removed, was manufactured through KOH wet etching. Then, SiO₂ was deposited on the LED wafer, on which the plurality of LED structures were formed, with a thickness of 60 nm as a first cover layer, Al₂O₃ was deposited with a thickness of 30 nm as a third cover layer, SiO₂ was deposited with a thickness of 60 nm as a second cover layer, and materials of the first cover layer, the third cover layer, and the second cover layer formed on an upper surface of the LED wafer between the LED structures were removed through RIE to expose an upper surface of the doped n-type III-nitride semiconductor layer between the LED structures and upper surfaces of the LED structures.

Thereafter, the doped n-type III-nitride semiconductor layer exposed on the side surface of the LED structure was etched using ICP in a width direction from both side surfaces toward the center. Then, a temporary first cover layer formed on the side surface of each LED structure was removed through RIE, and ultrasound was applied to the LED wafer to separate the plurality of LED structures. The separated LED structure was implemented to have a protrusion extending in a longitudinal direction with a predetermined width and protruding in a thickness direction on a lower surface of the doped n-type III-nitride semiconductor layer due to the etching in the width direction. In this case, a height from the p-type III-nitride semiconductor layer to the protrusion of the LED device, and the length and width of the LED device were manufactured to be the same as the thickness, length, and width of the ultra-thin LED device in Example 1, respectively.

### Experimental Example 1

Mounting electrode lines were manufactured on a base substrate made of quartz with a thickness of 500 μm such that the first lower electrode and the second lower electrode extending in a first direction were alternately formed to be spaced 3 μm from each other in a second direction perpendicular to the first direction. In this case, the first lower electrode and the second lower electrode each had a width of 10 μm and a thickness of 0.2 μm, materials of the first lower electrode and the second lower electrode were gold, and an area of a region where the LED device was mounted in the mounting electrode line was 1 mm². In addition, an insulating barrier made of SiO₂ with a height of 0.5 μm was formed on the base substrate to surround the area.

Thereafter, a solution was prepared by mixing with acetone with a dielectric constant of 20.7, 9 μl of the prepared solution was dropped twice onto 120 LED devices for examples and comparative examples in the area, a sine wave AC power of 40 Vpp at a frequency of 10 kHz was applied to the first lower electrode and the second lower electrode, and the LED device was mounted on the lower electrodes through dielectrophoresis.

### 1. Analysis of Mounting Surface

A SEM photograph was captured to observe and count the mounting surface of each LED device in contact with the upper surface of the lower electrode in the area, and a percentage compared to the number of LED device put into was shown in the following table 2.

In addition, a drivable mount ratio in which the mounting surface of the LED device become a first surface B or a second surface T and a selective mount ratio in which a specific one of the first surface B and the second surface T become the mounting surface for each example or each comparative example were shown in Table 2.

TABLE 2

| | | | | | | | | Mounting ratio | |
|---|---|---|---|---|---|---|---|---|---|
| | LED device | | | Mounting surface of LED device | | | | | Selective |
| | | | Second | Second | | First | | | mounting |
| | First | Second | cover layer | surface | Side | surface | | Drivable | (ratio/ |
| | surface B | surface T | (K(ω)) | T | surface | B | Total | mounting | surface) |
| Example 1 | pore/N | Selective | SiO₂/ | 94% | 6% | 0% | 100% | 94% | 94%/second |
| | | alignment | 0.336 | | | | | | surface |
| Example 2 | pore/N | orientation | SiNₓ/ | 94% | 4% | 2% | 100% | 96% | 94%/second |
| | | layer | 0.501 | | | | | | surface |
| Example 3 | pore/N | (ITO) | TiO₂/ | 54% | 25% | 21% | 100% | 75% | 54%/second |
| | | | 0.944 | | | | | | surface |
| Example 4 | pore/N | P | SiO₂/ | 12% | 17% | 71% | 100% | 83% | 71%/second |
| | | | 0.336 | | | | | | surface |
| Example 5 | pore/N | P | TiO₂/ | 14% | 30% | 56% | 100% | 70% | 56%/second |
| | | | 0.944 | | | | | | surface |
| Example 6 | non-pore/N | Selective | SiO₂/ | 93% | 6% | 1% | 100% | 94% | 93%/second |
| | | alignment | 0.336 | | | | | | surface |
| Example 7 | non-pore/N | orientation | Al₂O₃/ | 88% | 12% | 0% | 100% | 88% | 88%/second |
| | | layer | 0.616 | | | | | | surface |
| Example 8 | non-pore/N | (ITO) | TiO₂/ | 53% | 25% | 22% | 100% | 75% | 53%/second |
| | | | 0.944 | | | | | | surface |
| Example 9 | non-pore/N | P | SiO₂/ | 11% | 17% | 72% | 100% | 83% | 72%/second |
| | | | 0.336 | | | | | | surface |
| Comparative | pore/N | P | Non | 11% | 44% | 45% | 100% | 56% | 45%/second |
| Example 1 | | | | | | | | | surface |
| Comparative | non-pore/N | P | Non | 3% | 52% | 45% | 100% | 48% | —/ |
| Example 2 | | | | | | | | | side surface |
| Comparative | Protruding | P | Non | 7% | 57% | 36% | 100% | 43% | —/ |
| Example 3 | structure/N | | | | | | | | side surface |

In Table 2, N indicates an n-type III-nitride semiconductor layer, and P indicates a p-type III-nitride semiconductor layer.

As can be confirmed from Table 2, in the LED devices according to Comparative Examples 1 to 3, a ratio of drivable mounted LED devices to all the mounted LED devices is 56% or less, and thus a percentage in which the first surface B or the second surface T comes into contact with the upper surface of the mounting electrode is small, but in the LED devices according to the examples, a ratio of drivable mounting devices to all the mounted LED devices is 70% or more, and thus it can be seen that the first surface B or the second surface T has the characteristic of predominantly contacting the upper surface of the mounting electrode.

### Experimental Example 2

The LED devices according to Examples 1 to 3 were mounted on the mounting electrode line in the same manner as in Experimental Example 1, but dielectrophoresis was performed by changing the applied power conditions to a frequency of 10 kHz and a voltage of 20 Vpp. Thereafter, the form in which the LED devices were mounted was analyzed based on FIG. 12, and the results were shown in the following Table 3.

TABLE 3

| | LED device | | | | | Mounting form of | | |
|---|---|---|---|---|---|---|---|---|
| | | | Second | Mounting ratio (%) | | drivable mounting (%) | | |
| | First | Second | cover | | Side | Balanced | Biased | One |
| | surface | surface | layer | Drivable | surface | both ends | both ends | end |
| | B | T | (K(ω)) | mounting | mounting | mounting | mounting | mounting |
| Example 1 | pore/ | Selective | SiO₂/ | 99 | 1 | 46 | 52 | 1 |
| | N | alignment | 0.336 | | | | | |
| Example 2 | pore/ | orientation | SiNₓ/ | 99 | 1 | 37 | 61 | 1 |
| | N | layer | 0.501 | | | | | |
| Example 3 | pore/ | (ITO) | TiO₂/ | 88 | 12 | 36 | 41 | 11 |
| | N | | 0.944 | | | | | |

As can be confirmed from Table 3, in the case of Examples 1 and 2 having the second cover layer with a K(ω) real value of 0.6 or less, a mounting ratio, in which the both ends of the LED device are mounted on two adjacent mounting electrodes, is significantly higher than that of Example 3. Thus, it may be expected that Examples 1 and 2 have a more advantageous mounting form compared to Example 3 in forming a new driving electrode on the upper portion of the LED device.

A light-emitting diode (LED) device according to the present invention can prevent or minimize degradation in efficiency due to surface defects by significantly reducing an area of a photoactive layer exposed at a surface of the LED device and can repair even when surface defects occur so that degradation of light emission efficiency due to surface defects can be prevented.

In addition, it is very suitable for a method of self-aligning the LED device on an electrode using a dielectrophoretic force due to an electric field, and further, a top or bottom surface rather than a side surface comes into contact with the electrode after self-alignment so that drivable mounting efficiency can be increased. Furthermore, a specific surface of the top and bottom surfaces selectively comes into contact with a mounting electrode while minimizing a contact of the side surface, and thus a selection width of power used in light sources such as LED electrode assemblies and displays is expanded to DC power and high brightness is achieved so that the LED device can be widely applied as a component for displays and various light sources.

In addition, in the LED device according to one embodiment of the present invention, it can be prevented chemical damage to layers constituting the LED device due to various types of etchants applied during the manufacturing process of the LED device, and or it can be prevented an electrical short circuit generated due to exposure of a photoactive layer of the LED device due to an etchant applied after the LED device is self-aligned on the electrode.

Although exemplary embodiments of the present invention have been described, the spirit of the present invention is not limited to the exemplary embodiments disclosed herein, and it should be understood that numerous other embodiments can be devised by those skilled in the art that will fall within the same spirit and scope of the present invention through addition, modification, deletion, supplement, and the like of a component, and also these other embodiments will fall within the spirit and scope of the present invention.

What is claimed is:

1. A light-emitting diode (LED) device comprising:
a first surface and a second surface of which a first axis becomes a major axis based on the first axis and a second axis mutually perpendicular to each other and which are opposite to each other in a second axis direction in which a plurality of layers including a photoactive layer are stacked;
remaining side surfaces; and
a cover layer surrounding the remaining side surfaces,
wherein the cover layer includes:
a first cover layer configured to passivate the side surfaces in order to protect the side surfaces and remove a defect on the side surfaces; and
a second cover layer disposed on the first cover layer and configured to generate a rotational torque around an imaginary rotation axis passing through a center of the LED device in a first axis direction when an electric field and mobile medium are present.

2. The LED device of claim 1, wherein the plurality of layers includes an n-type conductive semiconductor layer, a photoactive layer, and a p-type conductive semiconductor layer.

3. The LED device of claim 1, wherein a length in the first axis direction ranges from 1 μm to 10 μm, and a thickness in the second axis direction ranges from 0.1 μm to 3 μm.

4. The LED device of claim 1, wherein the first cover layer has an electrical conductivity of 1×10⁻⁶ S/m or less.

5. The LED device of claim 1, wherein:
the LED device is an LED device for self-alignment using a dielectrophoretic force; and
the self-alignment is a method in which LED devices dispersed in the mobile medium move toward a mounting electrode generating an electric field, and one sides of the LED devices are aligned to come into contact with an upper surface of the mounting electrode.

6. The LED device of claim 1, wherein the second cover layer is a layer in which a real part of a K(ω) value according to the following Equation 1 satisfies more than 0 and 0.72 or less within at least some frequency ranges of a frequency range of 1 kHz or higher and 10 GHz or lower:
$$\\ \begin{matrix}K ( ω ) = \frac{{ε}_{p}^{{}_{} *} - {ε}_{m}^{{}_{} *}}{{ε}_{p}^{{}_{} *} + 2 {ε}_{m}^{{}_{} *}} & [ Equation 1 ]\end{matrix}$$
in Equation 1, K(ω) is an equation between εₚ* indicating a complex permittivity of a spherical core-shell particle made of GaN as a core portion and the second cover layer as a shell portion at an angular frequency ω and εₘ* indicating a complex permittivity of the mobile medium, and εₚ* is calculated according to the following Equation 2:
$$\\ \begin{matrix}{ε}_{p}^{{}_{} *} = {ε}_{2}^{{}_{} *} \frac{{( \frac{{R}_{2}}{{R}_{1}} )}^{3} + 2 ( \frac{{ε}_{1}^{{}_{} *} - {ε}_{2}^{{}_{} *}}{{ε}_{1}^{{}_{} *} + 2 {ε}_{2}^{{}_{} *}} )}{{( \frac{{R}_{2}}{{R}_{1}} )}^{3} - ( \frac{{ε}_{1}^{{}_{} *} - {ε}_{2}^{{}_{} *}}{{ε}_{1}^{{}_{} *} + 2 {ε}_{2}^{{}_{} *}} )} , & [ Equation 2 ]\end{matrix}$$
in Equation 2, R₁ denotes a radius of a core portion, R₂ denotes a radius of the core-shell particle, and ε₁* and ε₂* are complex permittivities of the core portion and a shell portion, respectively.

7. The LED device of claim 6, wherein a real part of a K(ω) value according to Equation 1 ranges from more than 0 to 0.62 or less.

8. The LED device of claim 1, wherein a thickness of the first cover layer ranges from 1 nm to 60 nm, and a thickness of the second cover layer ranges from 1 nm to 60 nm.

9. The LED device of claim 1, wherein the cover layer further includes a third cover layer serving as a resistance layer against dry and wet etching between the first cover layer and the second cover layer.

10. The LED device of claim 9, wherein the second cover layer and third cover layer have an etch ratio B/A of 2.0 more, which is a ratio between an etch rate A (nm/min) of the second cover layer and an etch rate B (nm/min) of the third cover layer under the same etching conditions.

11. The LED device of claim 9, wherein a thickness of the third cover layer ranges from 1 nm to 30 nm.

12. The LED device of claim 1, wherein a top layer having the second surface has a greater electrical conductivity coefficient than a bottom layer having the first surface.

13. The LED device of claim 12, wherein the electrical conductivity coefficient of the top layer is 10 times or more that of the bottom layer.

14. An ink composition comprising light-emitting diode (LED) devices according to claim 1 and a mobile medium.

15. An LED electrode assembly comprising a plurality of light-emitting diode (LED) devices each identical to the LED device according to claim 1,
wherein the first surface and the second surface of each of the plurality of LED devices are electrically connected to two electrodes spaced apart from each other in the second axis direction of the LED device.
